(19) United States
(12) Patent Application Publication
(10) Pub. No.: US 2007/0212568 A1
(43) Pub. Date: Sep. 13, 2007

(54) Organic Electroluminescent Device

(76) Inventor: Guofang Wang, Chiba (JP)

Correspondence Address: WENDEROTH, LIND & PONACK, L.L.P., 2033 K STREET N. W., SUITE 800, WASHINGTON, DC, 20006-1021, US

(21) Appl. No.: 10/593,462

(22) PCT Filed: Mar. 15, 2005
(86) PCT No.: PCT/JP05/04495

§ 371 Date: Sep. 19, 2006

(30) Foreign Application Priority Data
Mar. 19, 2004 (JP) 2004-080900

(51) Int. Cl. H01L 51/54

(52) U.S. Cl. 428/690; 428/917; 313/504; 257/40; 257/102; 257/103; 257/E51.049

(57) ABSTRACT

The present invention relates to an organic electroluminescent device comprising an anthracene derivative represented by Formula (1) shown below as a host and at least one selected from a perylene derivative, a borane derivative, a coumarin derivative, a pyran derivative, an iridium complex and a platinum complex as a dopant. The organic electroluminescent device of the present invention has a high efficiency, a long life, a low driving voltage and a high durability in storing and driving. 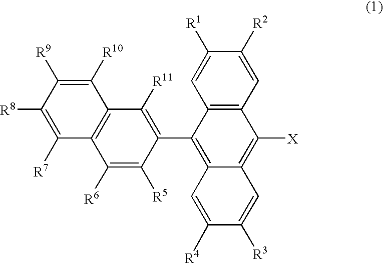
wherein R¹ to R⁴ and R¹² are independently hydrogen or alkyl having 1 to 12 carbon atoms; R⁵ to R¹¹ are independently hydrogen, alkyl having 1 to 12 carbon atoms, cycloalkyl having 3 to 12 carbon atoms or aryl having 6 to 12 carbon atoms; and Ar is non-condensed aryl represented by Formula (3); and m is an integer of 1 to 3; 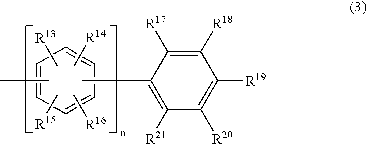
wherein n is an integer of 0 to 5; R¹³ to R²¹ are independently hydrogen, alkyl having 1 to 12 carbon atoms or aryl having 6 to 12 carbon atoms.

### BACKGROUND OF THE INVENTION

The present invention relates to an organic electroluminescent device (hereinafter abbreviated as an organic EL device) using a compound having an anthracene skeleton as a host for an emission layer, more specifically to an organic EL device which contributes to a high emission efficiency, a low driving voltage, an excellent heat resistance and a long life.

### RELATED ART

In recent years, attentions are paid to an organic EL device as a full color flat panel in the subsequent generation, and emission materials of blue, green and red colors are actively researched and developed. Among the emission materials, particularly a blue color emission material is requested to be improved. Blue color emission materials which have so far been reported are distyrylarylene derivatives (refer to, for example, JP H2-247278 A/1990: patent document 1), zinc metal complexes (refer to, for example, JP H6-336586 A/1994: patent document 2), aluminum complexes (refer to, for example, JP H5-198378 A/1993: patent document 3), aromatic amine derivatives (refer to, for example, JP H6-240248 A/1994: patent document 4) and anthracene derivatives (refer to, for example, JP H11-3782 A/1999: patent document 5) Examples in which the anthracene derivatives are used for emission materials are disclosed in Applied Physics Letters, 56 (9), 799 (1990) (non-patent document 1), JP H11-312588 A/1999 (patent document 6), JP H11-323323 A/1999 (patent document 7) and JP H11-329732 A/1999 (patent document 8) in addition to the patent document 5. A diphenylanthracene compound is used in the non-patent document 1, but there used to be the problems that the crystallizability is high and that the ability to form a thin film is inferior. Organic EL devices using derivatives having a phenylanthracene structure are disclosed as emission materials in the patent document 6, the patent document 7 and the patent document 8. Organic EL devices using anthracene derivatives substituted with naphthalene are disclosed as emission materials in the patent document 5. However, any of the above compounds has a symmetric molecular structure, and possibility of having a high crystallizability is concerned. Organic EL devices using compounds having two or more anthracene rings as emission materials in order to reduce a crystallizability to form a film having a good amorphous state are proposed in JP H8-12600 A/1996 (patent document 9), JP H11-111458 A/1999 (patent document 10), JP H12-344691 A/2000 (patent document 11) and JP H14-154993 A/2002 (patent document 12). It is reported that emission of a bluish green color is obtained by the above materials.

Proposed is a method in which a small amount of a fluorescent dye is doped in an emission layer in order to obtain a blue color organic EL device having a higher luminance and a longer life. An organic EL device in which an anthracene derivative substituted with naphthalene is used as a host compound and in which a perylene derivative is used as a dopant is disclosed in Applied Physics Letters, 80 (17), 3201 (2002) (non-patent document 2). An organic EL device in which an anthracene derivative substituted with naphthalene is used as a host compound and in which an amine-containing styryl derivative is used as a dopant is disclosed in International Publication No. 01/21729 (patent document 13).

In addition to the above, an example in which a phenylanthracene derivative substituted with naphthalene is used as a hole transport material is disclosed in JP H12-182776 A/2000 (patent document 14), but it is not used as an emission material.

### DISCLOSURE OF THE INVENTION

The present invention has been made in light of the problems involved in such conventional techniques as described above, and an object of the present invention is to provide an emission material contributing to a high emission efficiency, a low driving voltage, an excellent heat resistance and a long life of the device in an organic EL device, particularly an organic EL device using an emission material which is excellent in emission of a blue color as a host for an emission layer.

Intensive investigations repeated by the present inventors have resulted in finding that an organic EL device which has a high emission efficiency, a high luminance and a long life and which can be driven at a low voltage can be obtained by using for an emission layer of the organic EL device, a specific compound in which anthracene is a fundamental structure and which has an asymmetric structure in combination with other emission materials or emitting dopants, and they have completed the present invention based on the above knowledge.

Terms used in the present invention are defined as follows. Alkyl may be a linear group or a branched group. This applies to a case where optional —CH₂— in this group is This applies to a case where optional —CH₂— in this group is replaced by —O— or arylene. The term “optional” used in the optional. When plural groups or plural atoms are replaced by other groups, they each may be replaced by different groups. For example, a case where optional —CH₂— in alkyl may be replaced by —O— or phenylene shows that it may be any of alkoxyphenyl, alkoxyphenylalkyl, alkoxyalkylphenylalkyl, phenoxy, phenylalkoxy, phenylalkoxyalkyl, alkylphenoxy, alkylphenylalkoxy and alkylphenylalkoxyalkyl. The groups of alkoxy and alkoxyalkyl in the above groups may be linear groups or branched groups. Provided that when it is described in the present invention that optional —CH₂— may be replaced by —O—, a case where continuous plural —CH₂— are replaced by —O— is not included therein. Further, “a compound represented by Formula (1)”, “a group represented by Formula (2-1)” and “a group represented by Formula (4-1)” shall be shown by “a compound (1)”, “a group (2-1)” and “a group (4-1)” respectively in the present specification.

The problems described above are solved by the respective items shown below.
[1] An organic electroluminescent device which is sandwiched between an anode and a cathode and which comprises at least a hole transport layer, an emission layer and an electron transport layer, wherein the emission layer comprises an anthracene derivative represented by Formula (1) shown below as a host and at least one selected from a perylene derivative, a borane derivative, a coumarin derivative, a pyran derivative, an iridium complex and a platinum complex as a dopant: 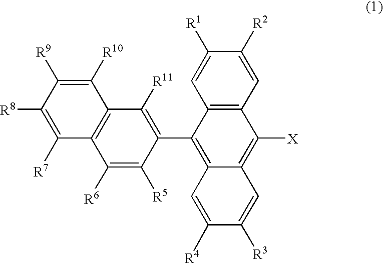
   wherein R¹ to R⁴ are independently hydrogen or alkyl having 1 to 12 carbon atoms, and optional —CH₂— in the above alkyl having 1 to 12 carbon atoms may be replaced by —O—; R⁵ to R¹¹ are independently hydrogen, alkyl having 1 to 12 carbon atoms, cycloalkyl having 3 to 12 carbon atoms or aryl having 6 to 12 carbon atoms, wherein optional —CH₂— in the above alkyl having 1 to 12 carbon atoms may be replaced by —O— or arylene having 6 to 12 carbon atoms; optional hydrogens in the above cycloalkyl having 3 to 12 carbon atoms may be replaced by alkyl having 1 to 12 carbon atoms or aryl having 6 to 12 carbon atoms; and optional hydrogens in the above aryl having 6 to 12 carbon atoms may be replaced by alkyl having 1 to 12 carbon atoms, cycloalkyl having 3 to 12 carbon atoms, aryl having 6 to 12 carbon atoms or non-condensed aryl having 12 to 18 carbon atoms; and X is one selected from the group of groups represented by Formulas (2-1) to (2-15) shown below: 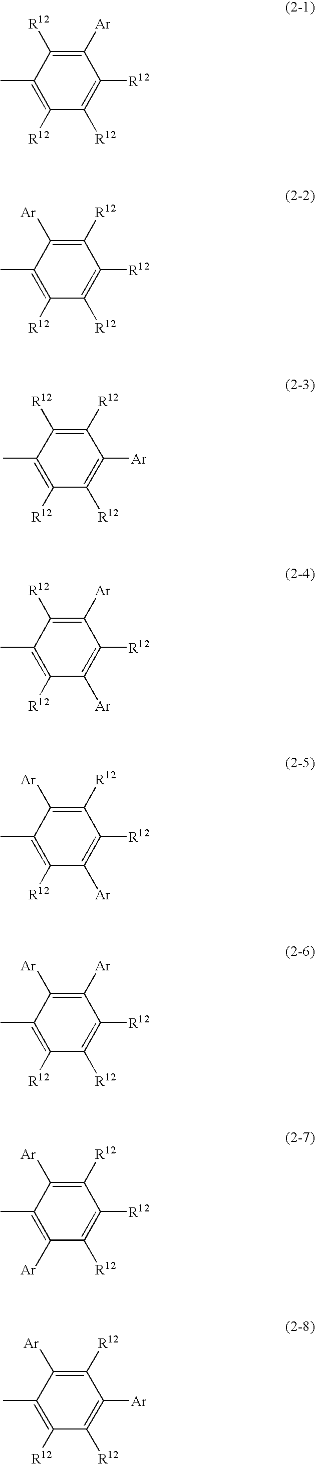 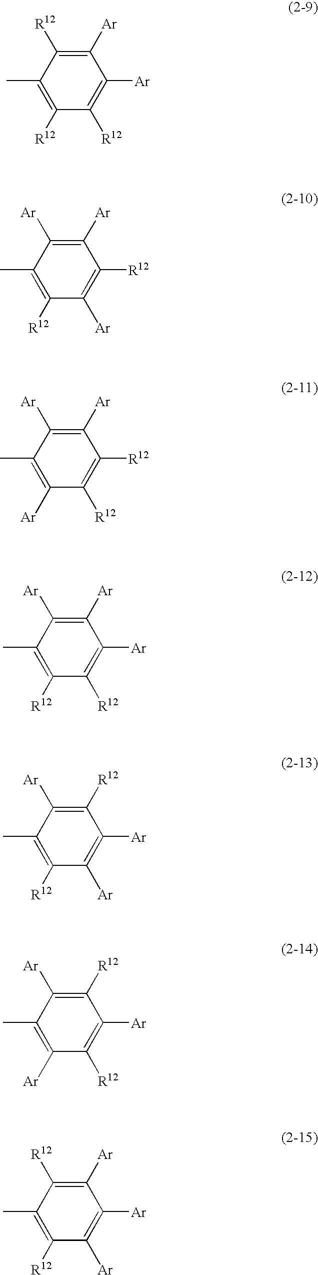
   in Formulas (2-1) to (2-15), R¹² is independently the same as that represented by R¹ to R⁴ in Formula (1); and Ar is independently non-condensed aryl represented by Formula (3): 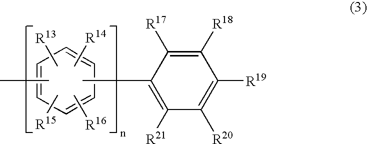
   wherein n is an integer of 0 to 5; R¹³ to R²¹ are independently hydrogen, alkyl having 1 to 12 carbon atoms or aryl having 6 to 12 carbon atoms; optional —CH₂— in the above alkyl having 1 to 12 carbon atoms may be replaced by —O—, and optional hydrogens in the above aryl having 6 to 12 carbon atoms may be replaced by alkyl having 1 to 12 carbon atoms, cycloalkyl having 3 to 12 carbon atoms or aryl having 6 to 12 carbon atoms.
[2] The organic electroluminescent device as described in the above item [1], wherein the emission layer comprises as a host, the anthracene derivative in which R¹ to R⁴ in Formula (1) are independently hydrogen, methyl or t-butyl; R⁵ to R¹¹ are independently hydrogen, methyl, t-butyl, phenyl, 1-naphthyl, 2-naphthyl, 4-t-butylphenyl or m-terphenyl-5′-yl; X is one selected from the group of the groups represented by Formulas (2-1) to (2-15); and in Formulas (2-1) to (2-15), R¹² is independently hydrogen, methyl or t-butyl.
[3] The organic electroluminescent device as described in the above item [1], wherein the emission layer comprises as a host, the anthracene derivative in which R¹ to R⁴ in Formula (1) are hydrogen; R⁵ to R¹¹ are independently hydrogen, phenyl, 1-naphthyl, 2-naphthyl or m-terphenyl-5′-yl; X is one selected from the group of the groups represented by Formulas (2-1) to (2-15); and in Formulas (2-1) to (2-15), R¹² is hydrogen.
[4] The organic electroluminescent device as described in the above item [1], wherein the emission layer comprises as a host, the anthracene derivative in which R¹ to R⁴ in Formula (1) are hydrogen; R⁵ to R¹¹ are independently hydrogen, phenyl, 1-naphthyl, 2-naphthyl or m-terphenyl-5′-yl; and X is one selected from the group of the groups represented by Formulas (2-1), (2-2), (2-4) to (2-6) and (2-10) shown below: 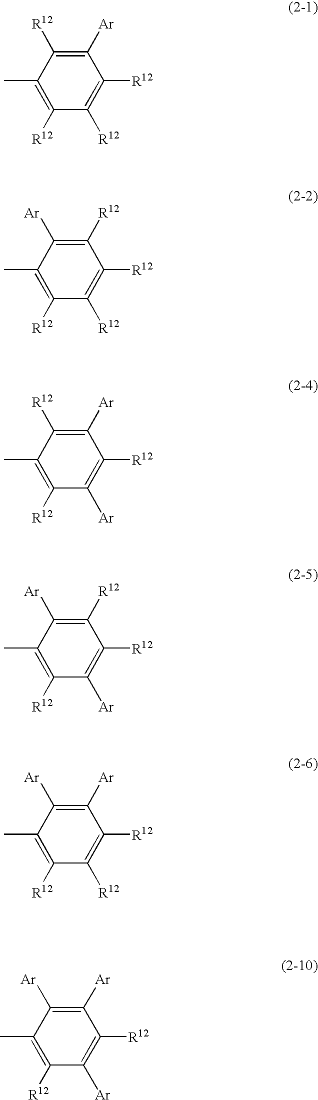
   in Formulas (2-1), (2-2), (2-4) to (2-6) and (2-10), R¹² is hydrogen; and Ar is independently one selected from the group of groups represented by Formulas (4-1) to (4-16) shown below: 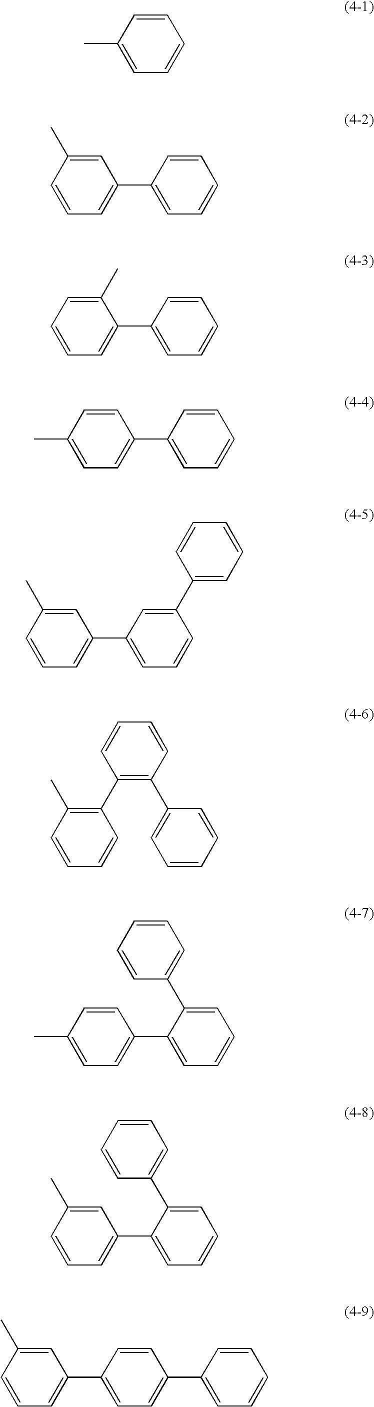 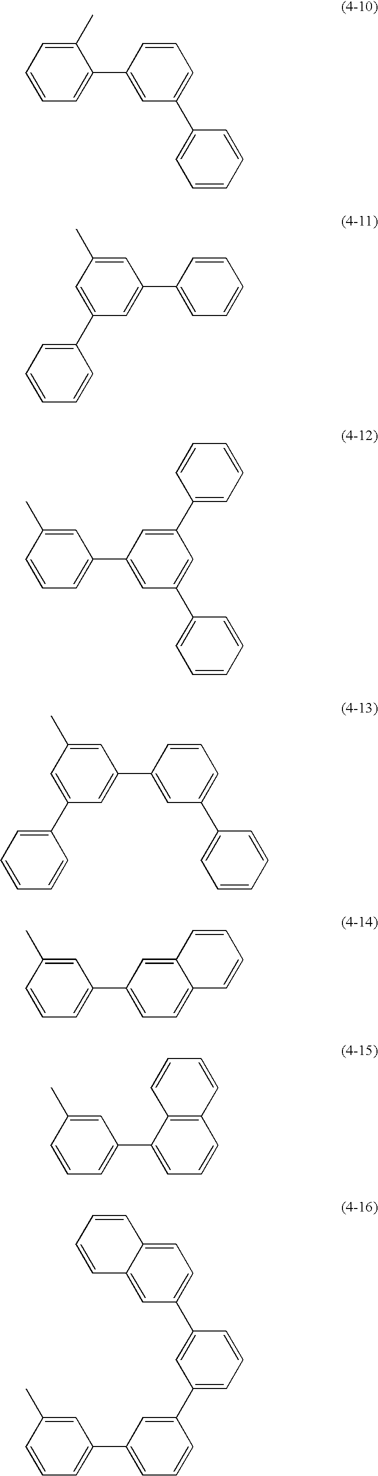
[5] The organic electroluminescent device as described in the above item [1], wherein the emission layer comprises as a host, the anthracene derivative in which R¹ to R⁴ in Formula (1) are hydrogen; R⁵ to R¹¹ are independently hydrogen, phenyl, (1) are hydrogen; R⁵ to R¹¹ are independently hydrogen, phenyl, selected from the group of the groups represented by Formulas (2-1), (2-2), (2-4) to (2-6) and (2-10): 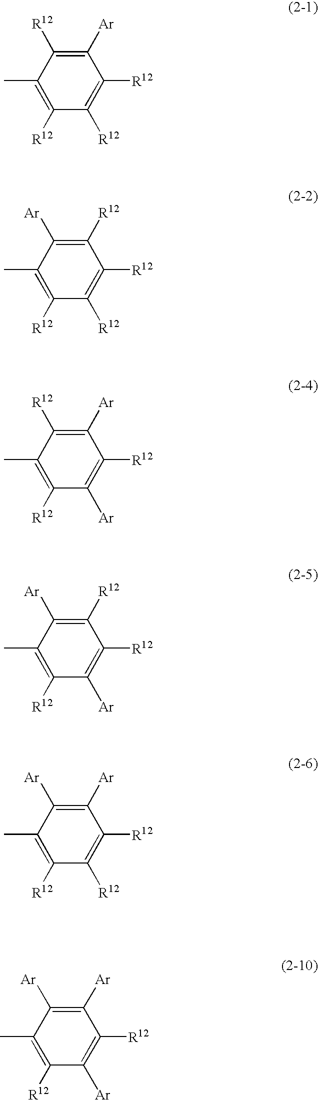
   in Formulas (2-1), (2-2), (2-4) to (2-6) and (2-10), R¹² is hydrogen; and Ar is independently one selected from the group of groups represented by Formulas (4-1) to (4-10) and (4-14) to (4-16) shown below: 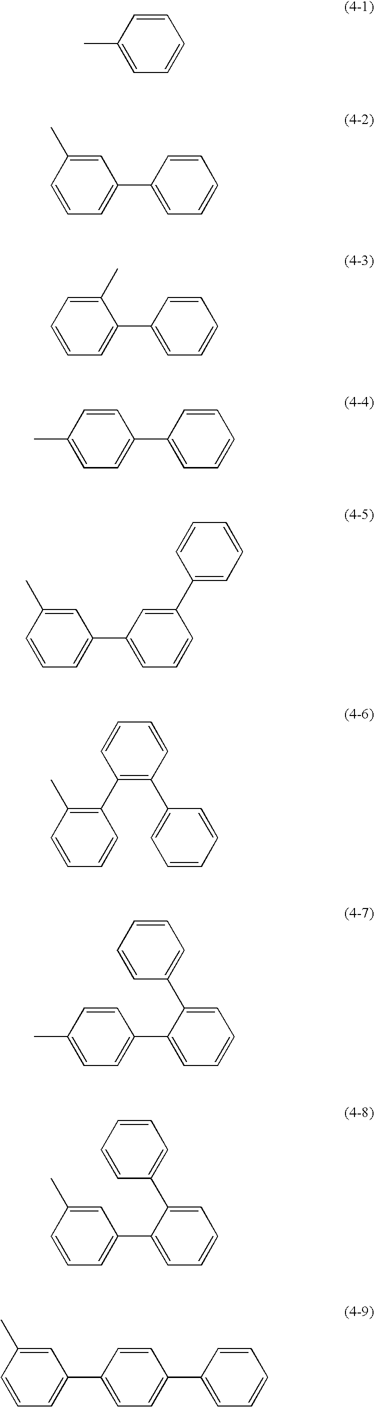 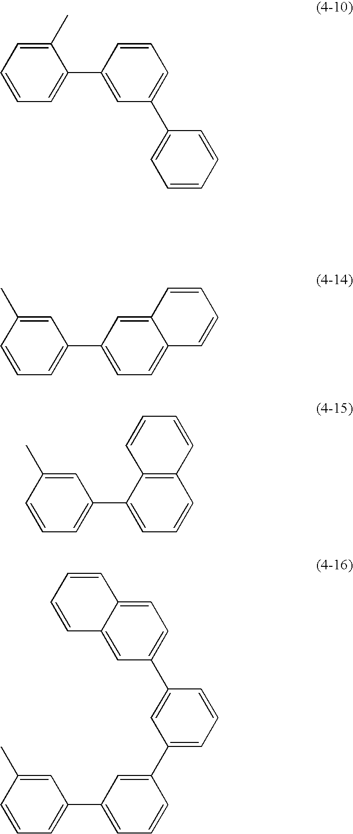
[6] The organic electroluminescent device as described in the above item [1], wherein the emission layer comprises as a host, the anthracene derivative in which R¹ to R⁴ in Formula (1) are hydrogen; R⁵ to R¹¹ are independently hydrogen, phenyl, (1) are hydrogen; R⁵ to R¹¹ are independently hydrogen, phenyl, selected from the group of the groups represented by Formulas (2-1), (2-2), (2-4) and (2-5): 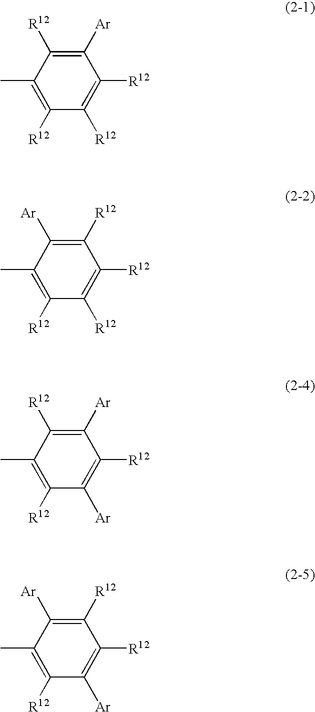
   in Formulas (2-1), (2-2), (2-4) and (2-5), R¹² is hydrogen; and Ar is independently one selected from the group of groups represented by Formulas (4-1) to (4-10) and (4-14) to (4-16) shown below: 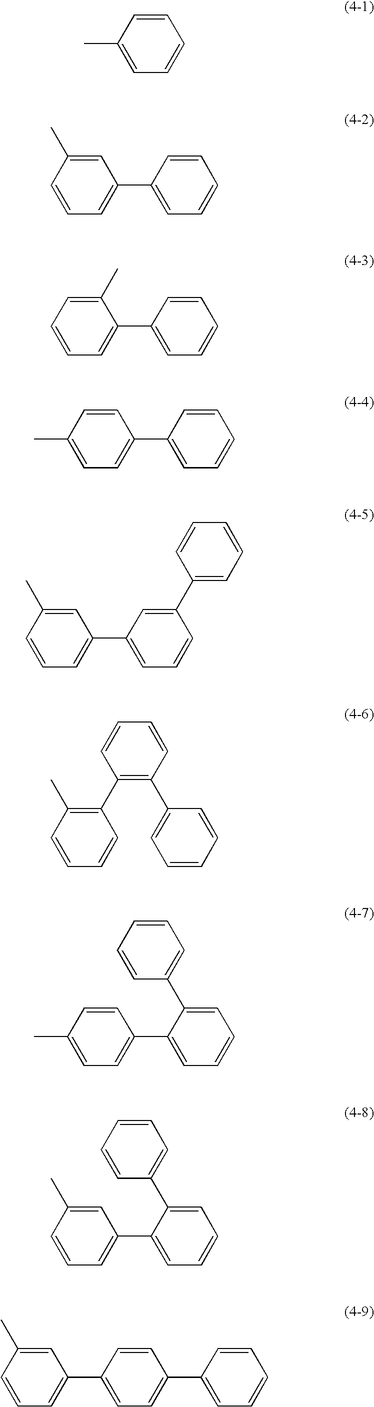 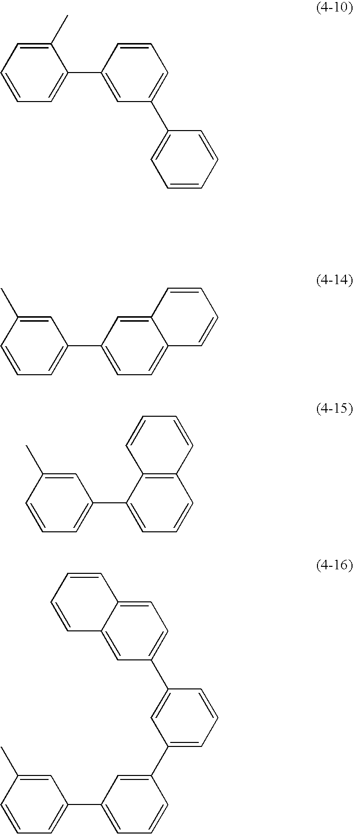
[7] The organic electroluminescent device as described in the above items [1] to [6], wherein the electron transport layer comprises a quinolyl base metal complex.
[8] The organic electroluminescent device as described in the above items [1] to [6], wherein the electron transport layer comprises at least one of a pyridine derivative and a phenanthroline derivative.
[9] The organic electroluminescent device as described in the above item [7], wherein the emission layer comprises the perylene derivative as a dopant.
[10] The organic electroluminescent device as described in the above item [8], wherein the emission layer comprises the perylene derivative as a dopant.
[11] The organic electroluminescent device as described in the above item [7], wherein the emission layer comprises the borane derivative as a dopant.
[12] The organic electroluminescent device as described in the above item [8], wherein the emission layer comprises the borane derivative as a dopant.
[13] The organic electroluminescent device as described in the above item [7], wherein the emission layer comprises the coumarin derivative as a dopant.
[14] The organic electroluminescent device as described in the above item [8], wherein the emission layer comprises the coumarin derivative as a dopant.
[15] The organic electroluminescent device as described in the above item [7], wherein the emission layer comprises the pyran derivative as a dopant.
[16] The organic electroluminescent device as described in the above item [8], wherein the emission layer comprises the pyran derivative as a dopant.
[17] The organic electroluminescent device as described in the above item [7], wherein the emission layer comprises the iridium complex as a dopant.
[18] The organic electroluminescent device as described in the above item [8], wherein the emission layer comprises the iridium complex as a dopant.
[19] The organic electroluminescent device as described in the above item [7], wherein the emission layer comprises the platinum complex as a dopant.
[20] The organic electroluminescent device as described in the above item [8], wherein the emission layer comprises the platinum complex as a dopant.

### MOST SUITABLE CONDITIONS FOR CARRYING OUT THE INVENTION

The present invention shall be explained below in further details.

The anthracene derivative used for the host in the emission layer in the organic electroluminescent device of the present invention is represented by Formula (1):

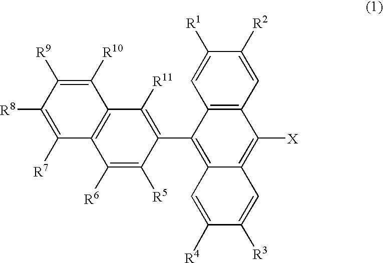

In Formula (1), R¹ to R⁴ are independently hydrogen or alkyl having 1 to 12 carbon atoms. The specific examples of the alkyl having 1 to 12 carbon atoms are methyl, ethyl, n-propyl, isopropyl, n-butyl, isobutyl, sec-butyl, t-butyl, n-pentyl, isopentyl, t-pentyl, neopentyl, n-hexyl, isohexyl, 1-methylpentyl, 2-methylpentyl, n-hexyl, isohexyl, 1-methylpentyl, 2-methylpentyl and 5-methylhexyl.

Optional —CH₂— in the above alkyl having 1 to 12 carbon atoms may be replaced by —O—. The specific examples of the alkyl having 1 to 12 carbon atoms in which optional —CH₂— is replaced by —O— are methoxy, ethoxy, propyloxy, isopropyloxy, n-butyloxy, isobutyloxy, sec-butyloxy, t-butyloxy, n-pentyloxy, isopentyloxy, t-pentyloxy, neopentyloxy, n-hexyloxy, isohexyloxy, 1-methylpentyloxy, 2-methylpentyloxy and n-hexyloxy.

The preferred examples of R¹ to R⁴ are hydrogen, methyl and t-butyl, and the particularly preferred example is hydrogen.

R⁵ to R¹¹ are independently hydrogen, alkyl having 1 to 12 carbon atoms, cycloalkyl having 3 to 12 carbon atoms or aryl having 6 to 12 carbon atoms. The specific examples of the alkyl having 1 to 12 carbon atoms are methyl, ethyl, n-propyl, isopropyl, n-butyl, isobutyl, sec-butyl, t-butyl, n-pentyl, isopentyl, t-pentyl, neopentyl, n-hexyl, isohexyl, 1-methylpentyl, 2-methylpentyl, n-hexyl, isohexyl, 1-methylpentyl, 2-methylpentyl and 5-methylhexyl.

Optional —CH₂— in the above alkyl having 1 to 12 carbon atoms may be replaced by —O— or arylene having 6 to 12 carbon atoms. The specific examples of the alkyl having 1 to 12 carbon atoms in which optional —CH₂— is replaced by —O— are methoxy, ethoxy, propyloxy, isopropyloxy, n-butyloxy, isobutyloxy, sec-butyloxy, t-butyloxy, n-pentyloxy, isopentyloxy, t-pentyloxy, neopentyloxy, n-hexyloxy, isohexyloxy, 1-methylpentyloxy, 2-methylpentyloxy and n-hexyloxy. The specific examples of the alkyl having 1 to 12 carbon atoms in which optional —CH₂— is replaced by arylene having 6 to 12 carbon atoms are 2-phenylethyl, 2-(4-methylphenyl)ethyl, 1- methyl-1-phenylethyl, 1,1-dimethyl-2-phenylethyl and trityl.

The specific examples of the alkyl having 1 to 12 carbon atoms in which optional —CH₂— is replaced by —O— and in which optional —CH₂— is replaced by arylene having 6 to 12 carbon atoms are phenoxy, o-tolyloxy, m-tolyloxy, p-tolyloxy, 1-naphthoxy, 2-naphthoxy, 2,4-dimethylphenoxy, 2,6-dimethylphenoxy, 2,4,6-trimethylphenoxy, 4-t-butylphenoxy, 2,4-di-t-butylphenoxy, 2,4,6-tri-t-butylphenoxy, 2-phenylethoxy and 2-(4-methylphenyl)ethoxy.

The specific examples of the cycloalkyl having 3 to 12 carbon atoms are cyclopropyl, cyclobutyl, cyclopentyl and cyclohexyl.

Optional hydrogens in the above cycloalkyl having 3 to 12 carbon atoms may be replaced by alkyl having 1 to 12 carbon atoms or aryl having 6 to 12 carbon atoms. The specific examples of the cycloalkyl having 3 to 12 carbon atoms in which optional hydrogens are replaced by alkyl having 1 to 12 carbon atoms are 2-methylcyclohexyl, 3-methylcyclohexyl, 4-methylcyclohexyl, 2,4,6-trimethylcyclohexyl, 2-tert-butylcyclohexyl, 3-tert-butylcyclohexyl, 4-tert-butylcyclohexyl and 2,4,6-tri-tert-butylcyclohexyl. The specific examples of the cycloalkyl having 3 to 12 carbon atoms in which optional hydrogens are replaced by aryl having 6 to 12 carbon atoms are 4-phenylcyclohexyl and the like.

The specific examples of the aryl having 6 to 12 carbon atoms are phenyl, 1-naphthyl and 2-naphthyl.

Optional hydrogens in the above aryl having 6 to 12 carbon atoms may be replaced by alkyl having 1 to 12 carbon atoms, cycloalkyl having 3 to 12 carbon atoms or having 6 to 12 carbon atoms. The specific examples of the aryl having 6 to 12 carbon atoms in which optional hydrogens are replaced by the alkyl having 1 to 12 carbon atoms are o-tolyl, m-tolyl, p-tolyl, 2-biphenylyl, 3-biphenylyl, 4-biphenylyl, 2,4-dimethylphenyl, 2,6-dimethylphenyl, 2,4,6-trimethylphenyl, 4-t-butylphenyl, 2,4-di-t-butylphenyl and 2,4,6-tri-t-butylphenyl. The specific examples of the aryl having 6 to 12 carbon atoms in which optional hydrogens are replaced by the cycloalkyl having 3 to 12 carbon atoms are 4-cyclohexylphenyl and the like. The specific examples of the aryl having 6 to 12 carbon atoms in which optional hydrogens are replaced by the aryl having 6 to 12 carbon atoms are m-terphenyl-2′-yl, m-terphenyl-4′-yl, m-terphenyl-5′-yl, o-terphenyl-3′-yl, o-terphenyl-4′-yl and p-terphenyl-2′-yl. The specific examples of the aryl having 6 to 12 carbon atoms in which optional hydrogens are replaced by non-condensed aryl having 12 to 18 carbon atoms are m-terphenyl-2-yl, m-terphenyl-3-yl, m-terphenyl-4-yl, o-terphenyl-2-yl, o-terphenyl-3-yl, o-terphenyl-4-yl, p-terphenyl-2-yl, p-terphenyl-3-yl, p-terphenyl-4-yl, 5′-phenyl-m-terphenyl-2-yl, 5′-phenyl-m-terphenyl-3-yl, 5′-phenyl-m-terphenyl-4-yl and m-quaterphenyl.

The preferred examples of R⁵ to R¹¹ are hydrogen, methyl, t-butyl, phenyl, 1-naphthyl, 4-t-butylphenyl and m-terphenyl-5′-yl. The more preferred examples are hydrogen, phenyl, 1-naphthyl, 2-naphthyl and m-terphenyl-5′-yl.

X is one selected from the groups (2-1) to (2-15) shown below. Preferred X is the group (2-1), (2-2), (2-4), (2-5) (2-6) or (2-10), and particularly preferred X is the group (2-1), (2-2), (2-4), (2-5) or (2-5).

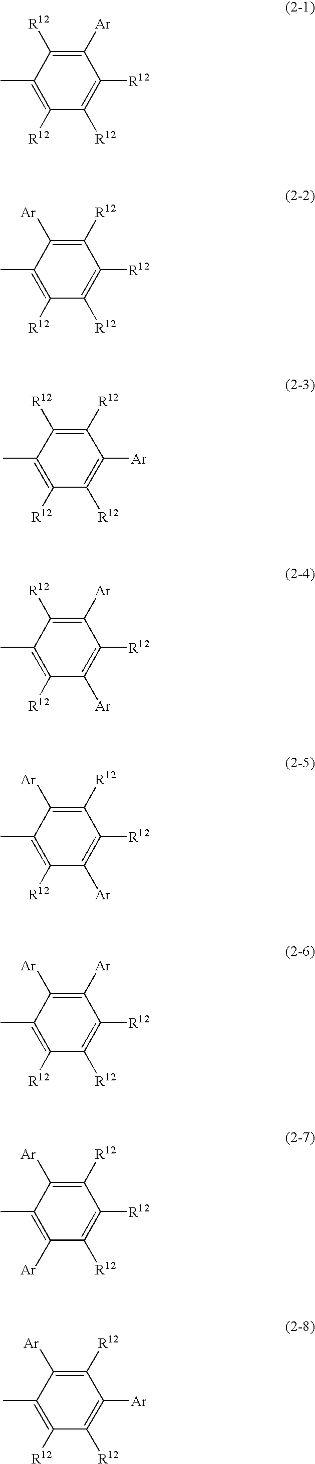

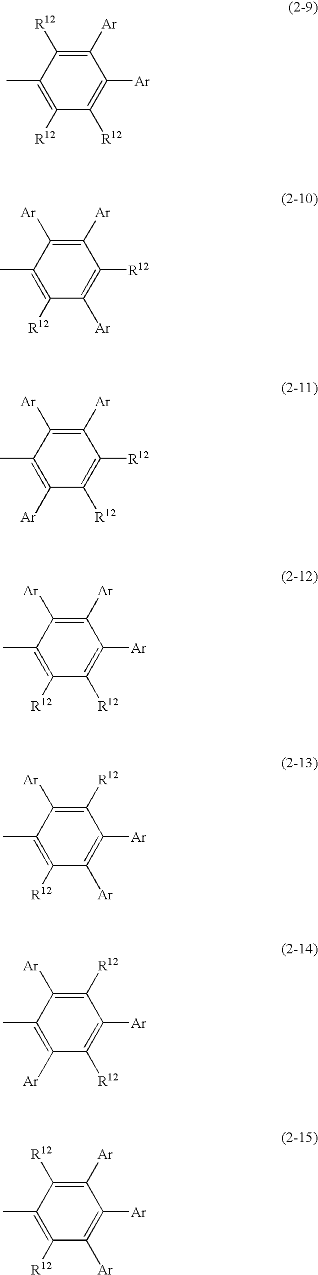

Ar in the groups (2-1) to (2-15) is non-condensed aryl represented by Formula (3) as shall be described later in details, and it has an important role to form characteristics as an emission material for the compound (1). When Ar is substituted in an ortho position based on a position combined with anthracene in phenyl of X, an emission wavelength of a blue color originating in the fundamental skeleton can be maintained, and therefore it is preferred. When Ar is substituted in the para position, the compound has an enhanced rigidity, an excellent heat resistance and an elongated life. When Ar is substituted in the meta position, characteristics staying in the middle of both are brought to the compound. Considering an emission wavelength, a heat resistance and a life which are expected to the emission material based on the design of the device, the number of Ar substituted and the position thereof are suitably selected, whereby the compound which is consistent with the object can be obtained.

R¹² is the same as R¹ to R⁴ in Formula (1). The specific examples thereof are the same as the specific examples of R¹ to R⁴ described above. The preferred examples of R¹² are hydrogen, methyl and t-butyl, and the more preferred example is hydrogen.

In any one of the groups (2-1) to (2-15), plural R¹² may be the same or different. In any one of the groups (2-2) to (2-15), plural Ar may be the same or different.

Ar is non-condensed aryl represented by Formula (3): 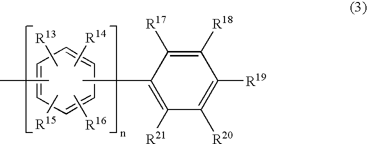
in Formula (3), n is an integer of 0 to 5, preferably 0 to 3.

The non-condensed aryl as a substituent for substituting optional hydrogens in the aryl having 6 to 12 carbon atoms described above is a monovalent group constituted by at least two monocyclic aromatic groups. The specific examples thereof are monovalent groups derived from biphenyl and terphenyl. Ar shall include phenyl in terms of the definition described above. When n is an integer of 1 to 5, phenylene in the middle is independently selected optionally from 1,2-phenylene, 1,3-phenylene and 1,4-phenylene. When 1,2-phenylene is selected, an emission wavelength of a blue color originating in the fundamental skeleton can be maintained, and therefore it is preferred. When 1,4-phenylene is selected, the compound is characterized by having an enhanced rigidity, an excellent heat resistance and an elongated life. 1,3-Phenylene brings characteristics staying in the middle of both to the compound. Considering an emission wavelength, a heat resistance and a life which are expected to the emission material based on the design of the device, the conditions of the number of n and the kind of phenylene are added to the conditions of Ar described above, whereby the compound which is consistent with the object can be obtained.

R¹³ to R²¹ are independently hydrogen, alkyl having 1 to 12 carbon atoms or aryl having 6 to 12 carbon atoms. The specific examples of the alkyl having 1 to 12 carbon atoms are methyl, ethyl, n-propyl, isopropyl, n-butyl, isobutyl, sec-butyl, t-butyl, n-pentyl, isopentyl, t-pentyl, neopentyl, n-hexyl, isohexyl, 1-methylpentyl, 2-methylpentyl, n-hexyl, isohexyl, 1-methylpentyl, 2-methylpentyl and 5-methylhexyl.

Optional —CH₂— in the above alkyl having 1 to 12 carbon atoms may be replaced by —O—. The specific examples of the alkyl having 1 to 12 carbon atoms in which optional —CH₂— is replaced by —O— are methoxy, ethoxy, propyloxy, isopropyloxy, n-butyloxy, isobutyloxy, sec-butyloxy, t-butyloxy, n-pentyloxy, isopentyloxy, t-pentyloxy, neopentyloxy, n-hexyloxy, isohexyloxy, 1-methylpentyloxy, 2-methylpentyloxy and n-hexyloxy.

The specific examples of the aryl having 6 to 12 carbon atoms are phenyl, 1-naphthyl and 2-naphthyl.

Optional hydrogens in the above aryl having 6 to 12 carbon atoms may be replaced by alkyl having 1 to 12 carbon atoms, cycloalkyl having 3 to 12 carbon atoms or aryl having 6 to 12 carbon atoms. The specific examples of the aryl having 6 to 12 carbon atoms in which optional hydrogens are replaced by the alkyl having 1 to 12 carbon atoms are o-tolyl, m-tolyl, p-tolyl, 2-biphenylyl, 3-biphenylyl, 4-biphenylyl, 2,4-dimethylphenyl, 2,6-dimethylphenyl, 2,4,6-trimethylphenyl, 4-t-butylphenyl, 2,4-di-t-butylphenyl and 2,4,6-tri-t-butylphenyl. The specific examples of the aryl having 6 to 12 carbon atoms in which optional hydrogens are replaced by the cycloalkyl having 3 to 12 carbon atoms are 4-cyclohexylphenyl and the like. The specific examples of the aryl having 6 to 12 carbon atoms in which optional hydrogens are replaced by the aryl having 6 to 12 carbon atoms are m-terphenyl-2′-yl, m-terphenyl-4′-yl, m-terphenyl-5′-yl, o-terphenyl-3′-yl, o-terphenyl-4′-yl and p-terphenyl-2′-yl.

The preferred examples of R¹³ to R²¹ are different according to a position in which Ar described above is substituted on a phenyl group, whether phenylene in the middle of Ar is 1,2-phenylene, 1,3-phenylene or 1,4-phenylene and the number of n. When aryl such as phenyl and naphthyl is substituted in an ortho position based on a position combined with a fundamental skeleton side in phenylene substituted, an emission wavelength of a blue color originating in the fundamental skeleton can be maintained. When the aryl is substituted in the para position, the compound has an enhanced rigidity, an excellent heat resistance and an elongated life. When the aryl is substituted in the meta position, characteristics staying in the middle of both are brought to the compound. Considering a wavelength, a heat resistance and a life which are expected to the emission material based on the design of the device, the conditions of the number of R¹³ to R²¹ and the positions thereof are added to the conditions of Ar described above, the number of n and the kind of phenylene, whereby the compound which is consistent with the object can be obtained.

The specific examples of Ar are the following groups (4-1) to (4-16), but the present invention shall not be restricted by the disclosure of these specific groups. Preferred Ar is the groups (4-1) to (4-10) and (4-14) to (4-16).

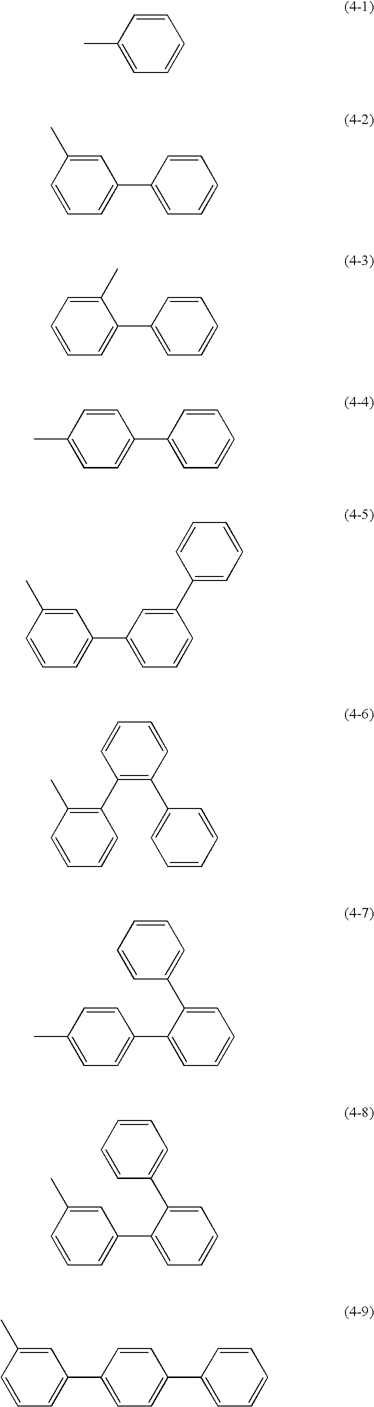

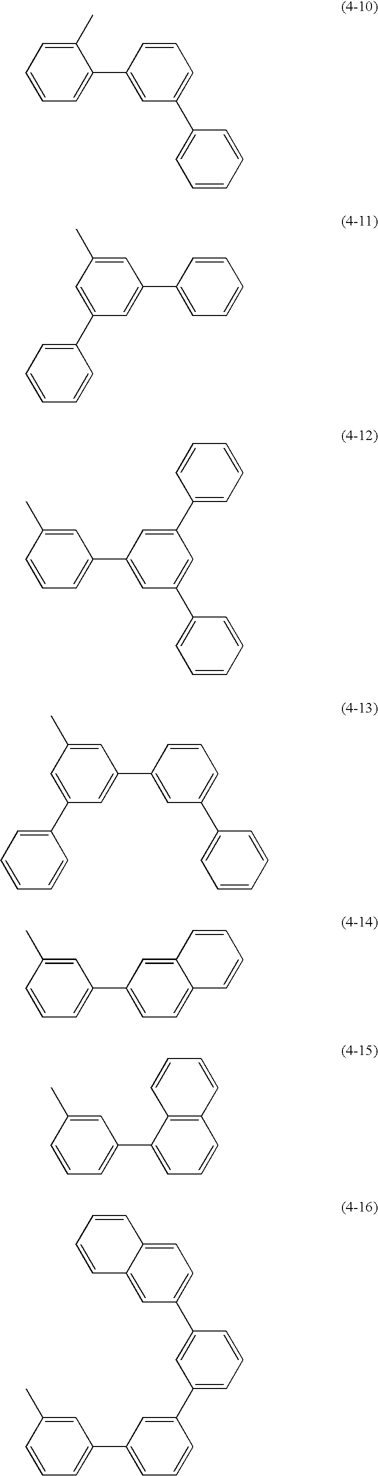

The specific examples of the emission layer host used for the emission layer in the organic EL device of the present invention are the following compounds of Formulas (5) to (89), but the present invention shall not be restricted by the disclosure of these specific structures.

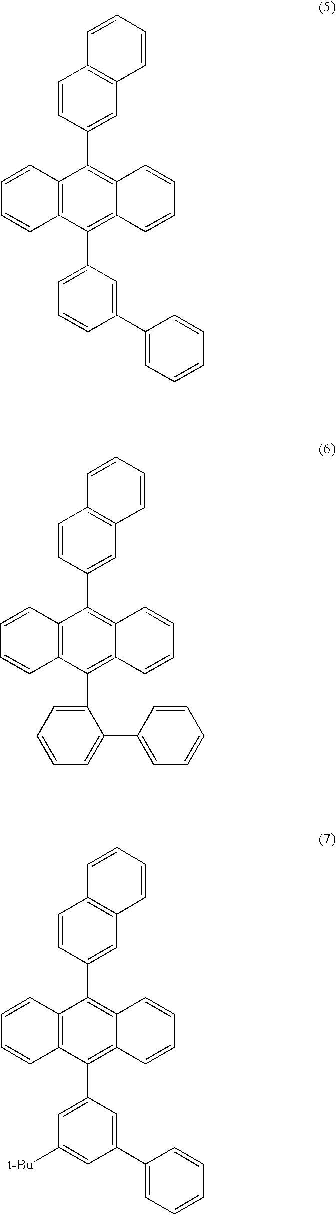

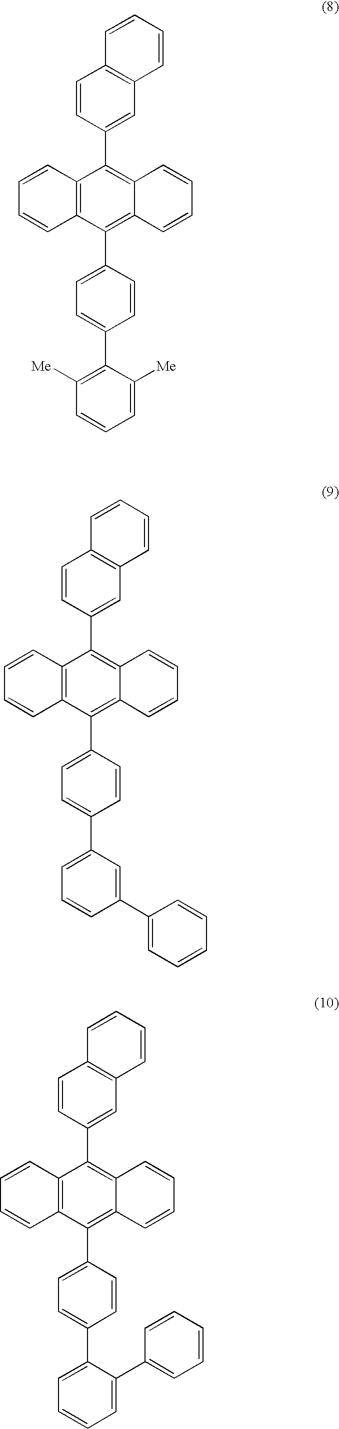

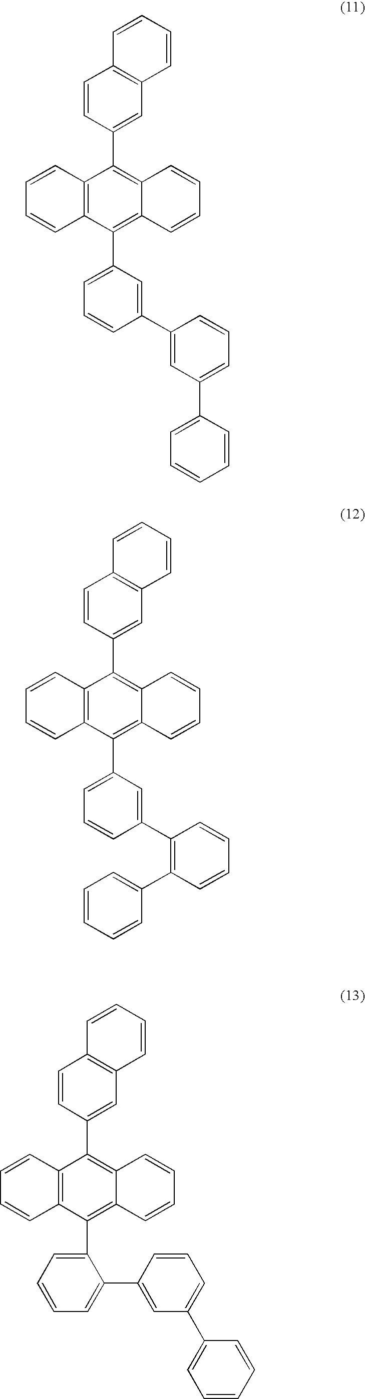

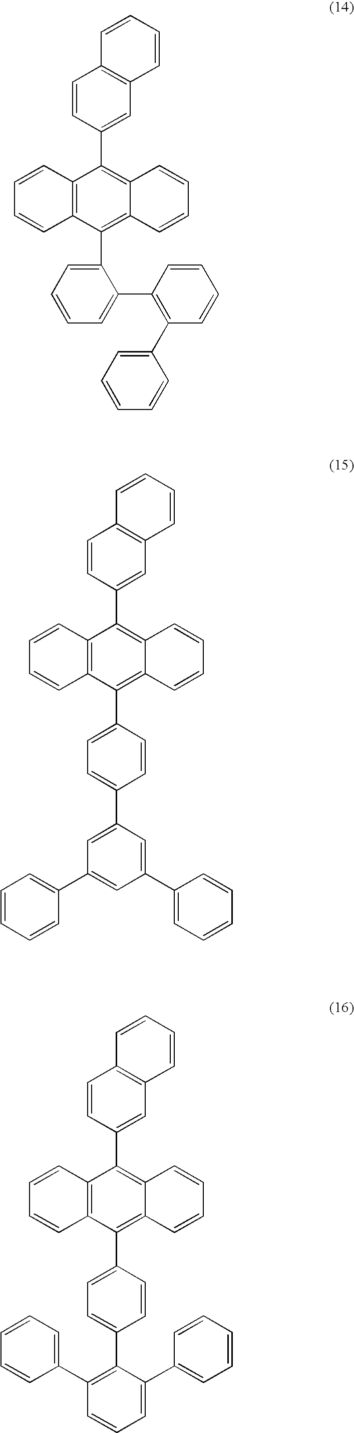

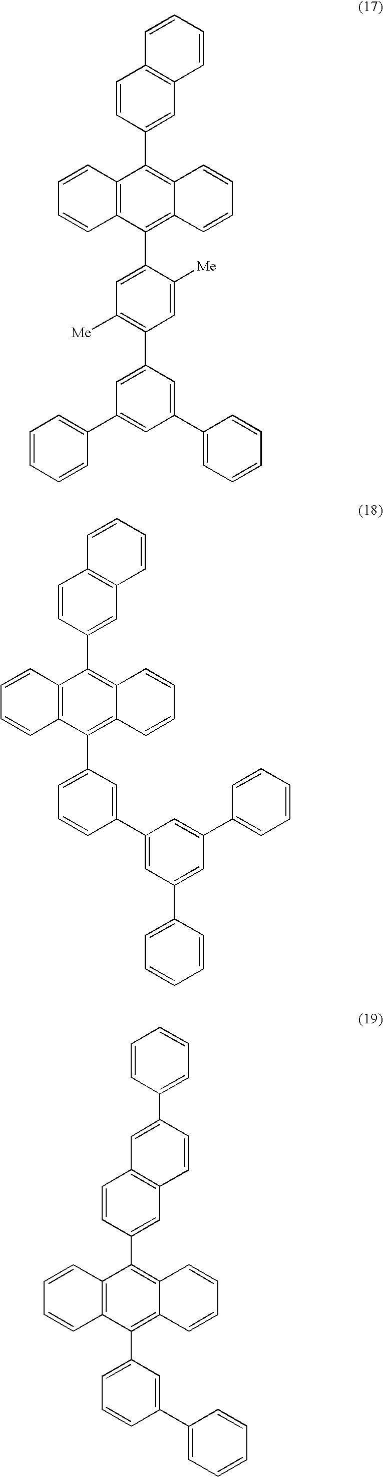

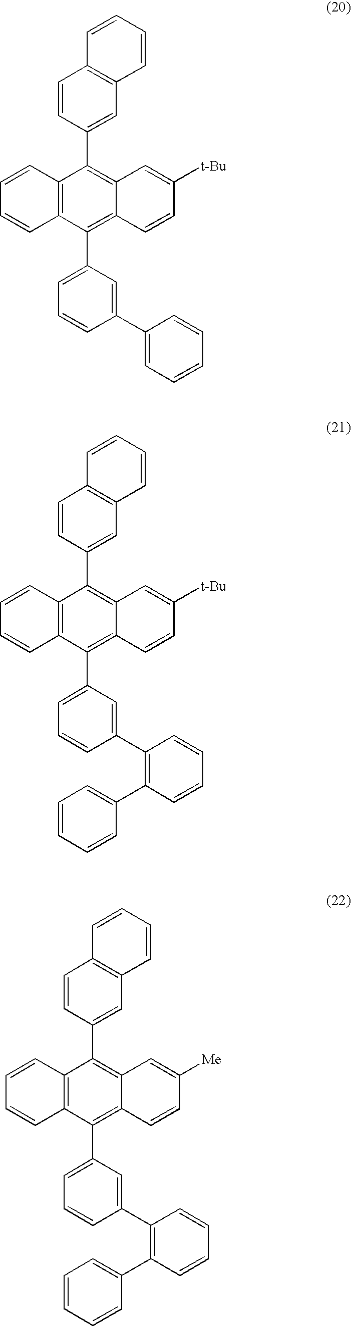

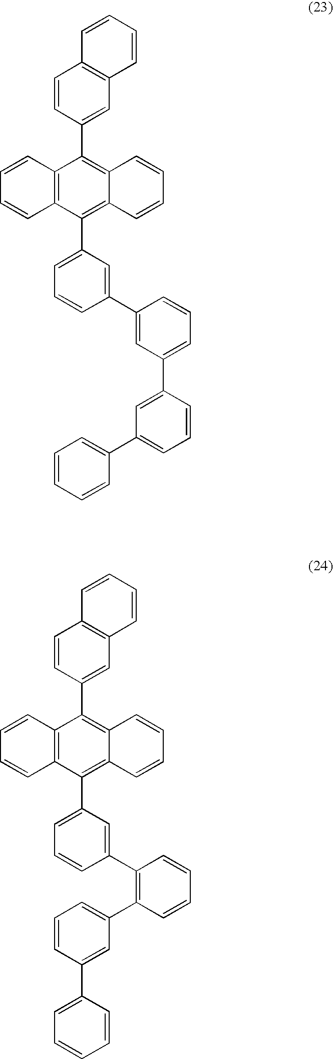

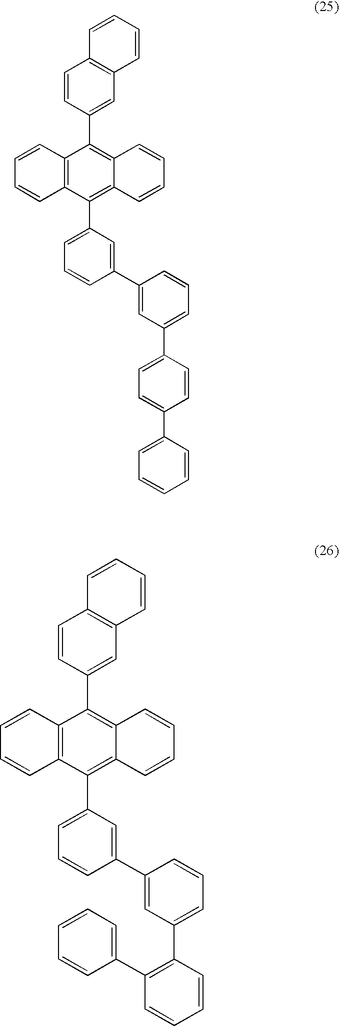

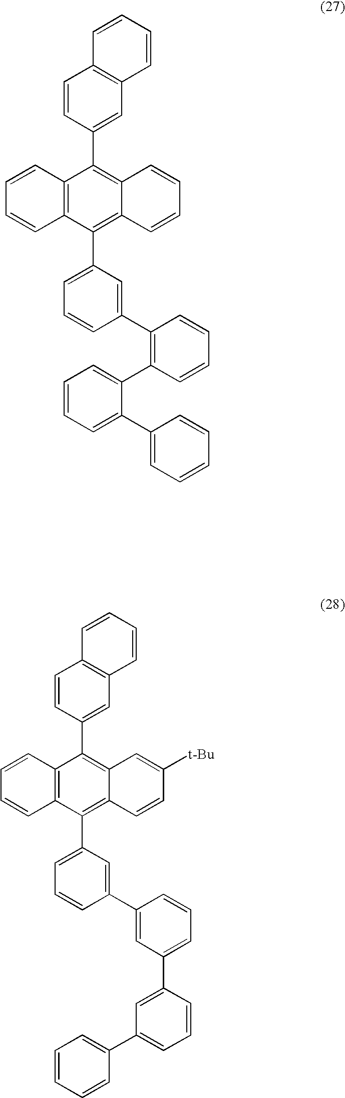

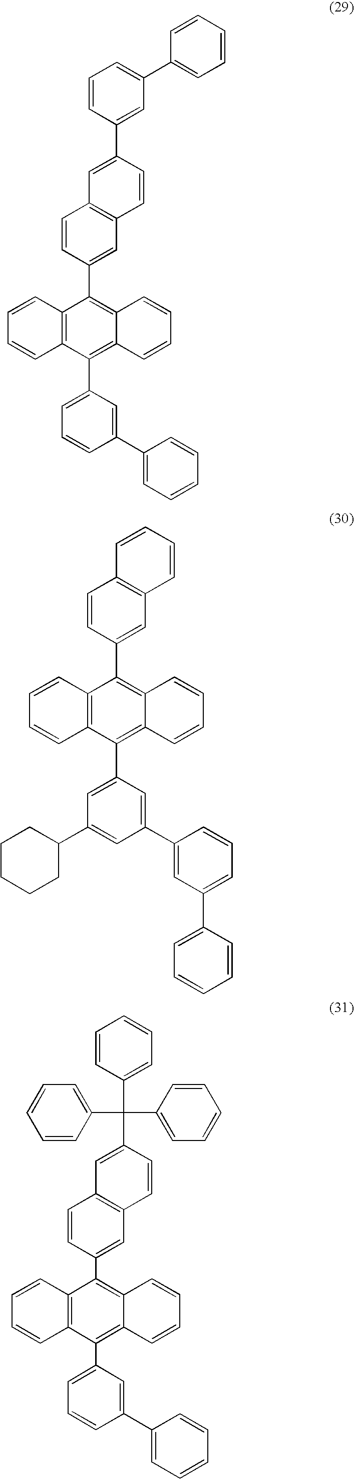

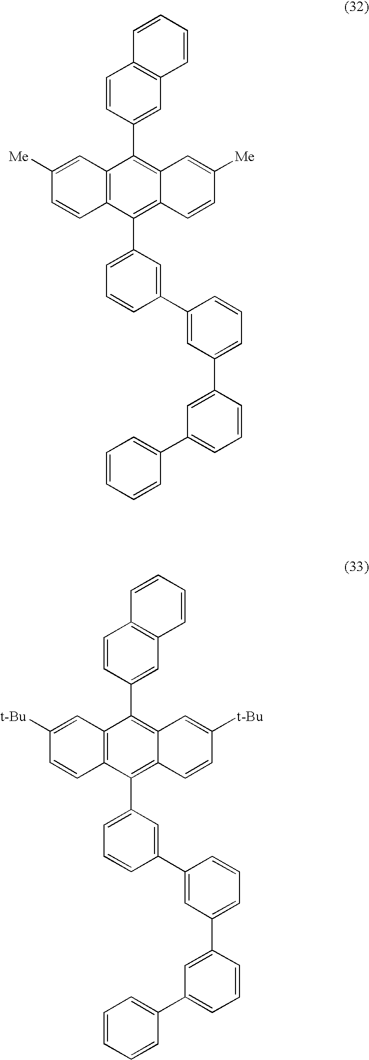

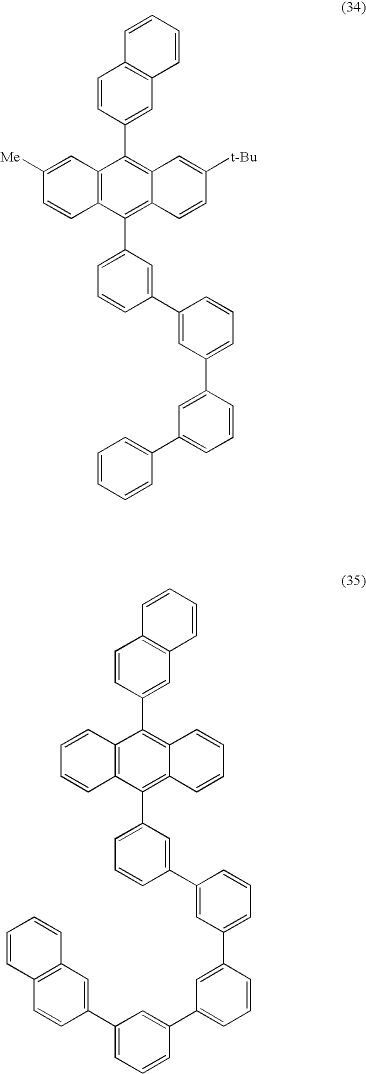

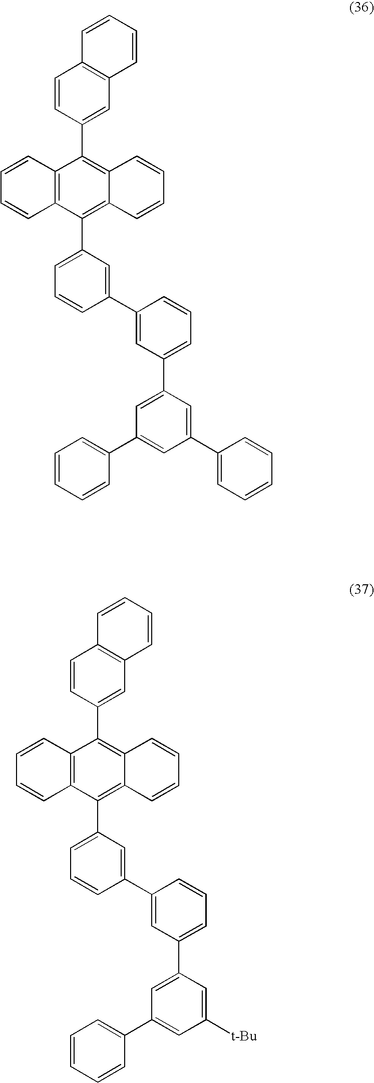

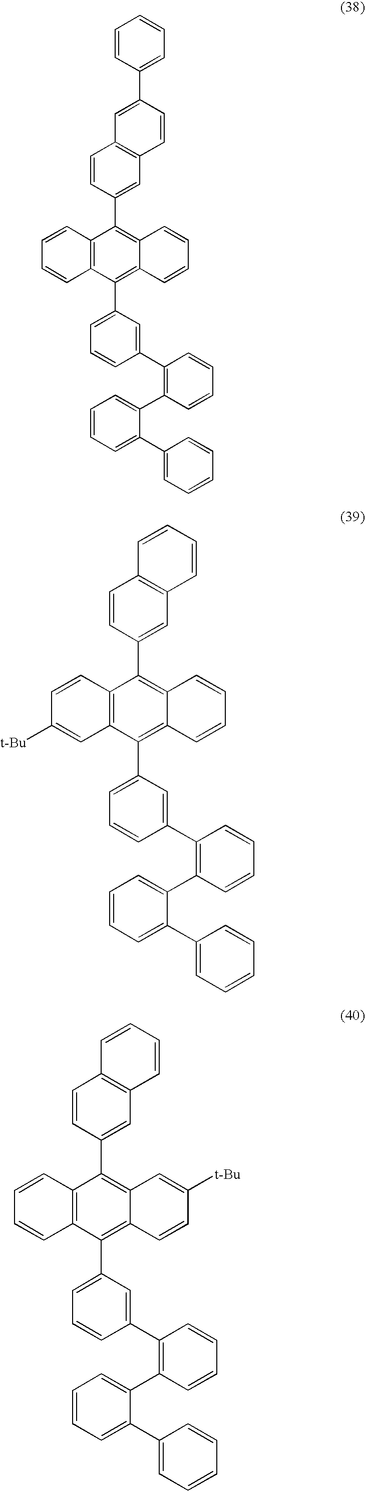

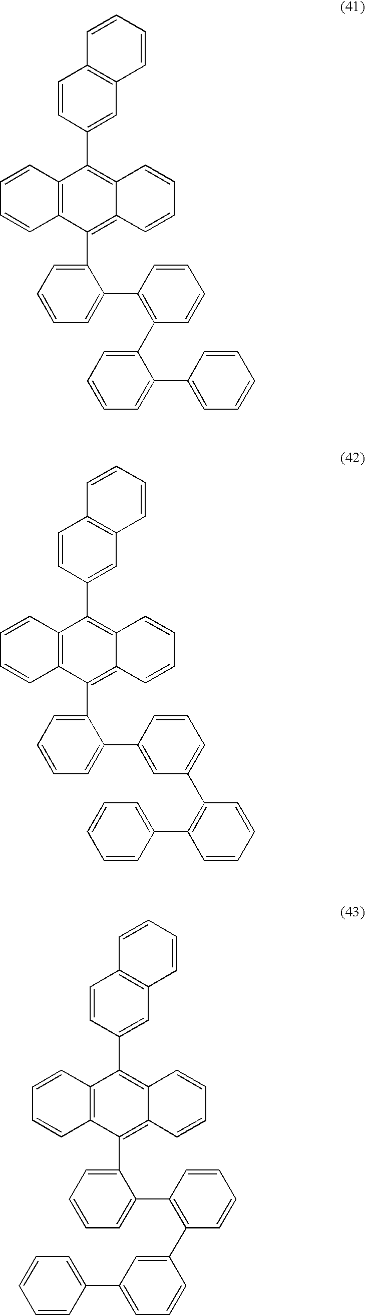

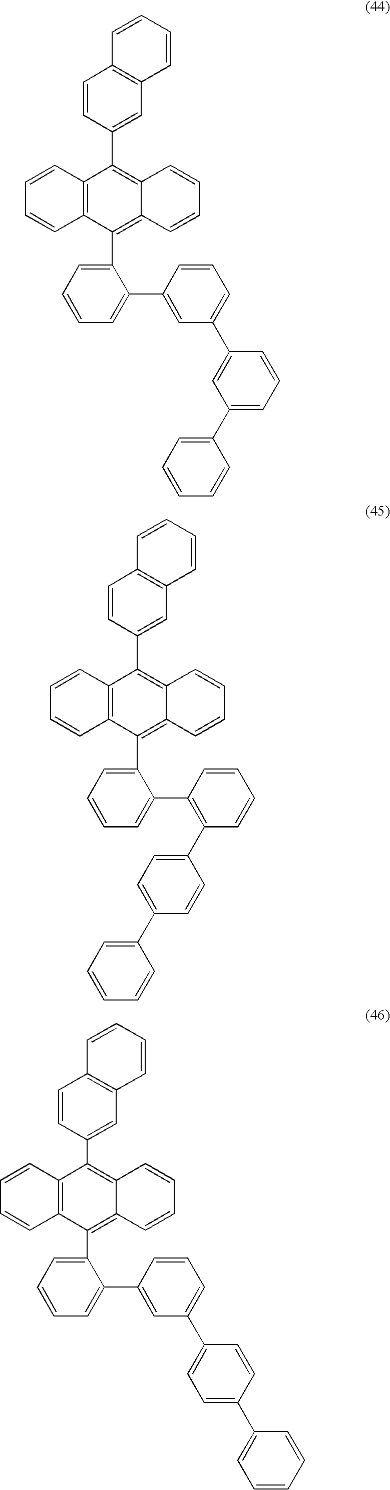

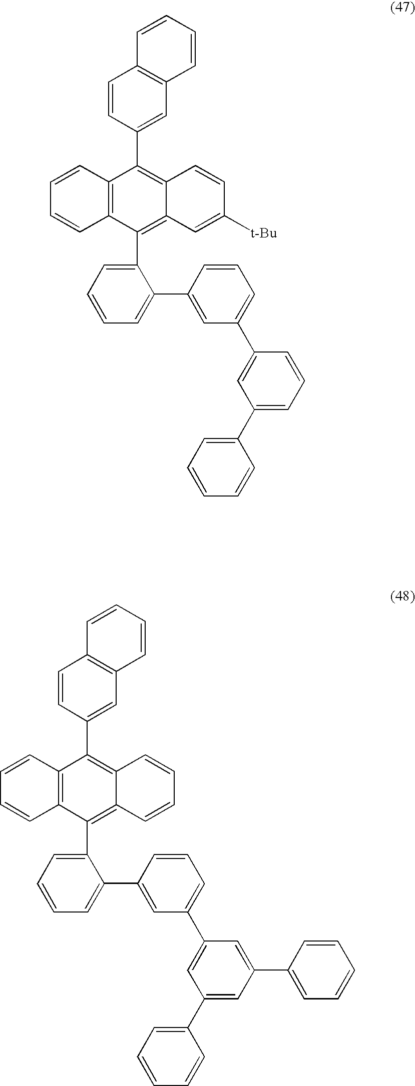

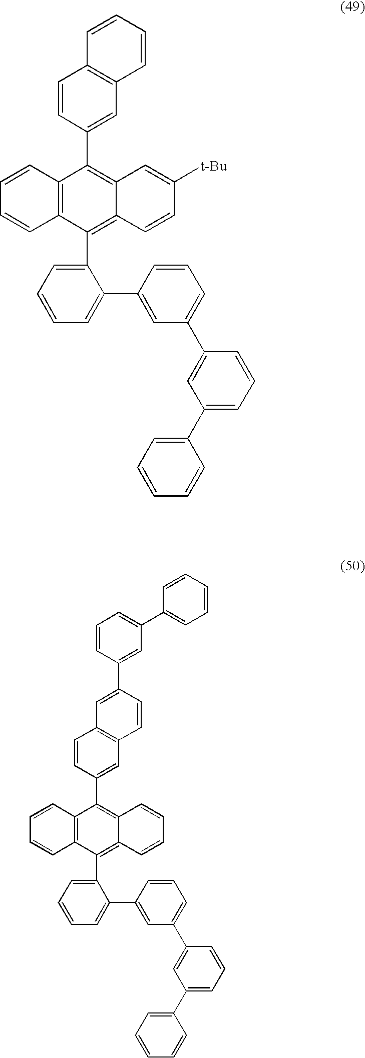

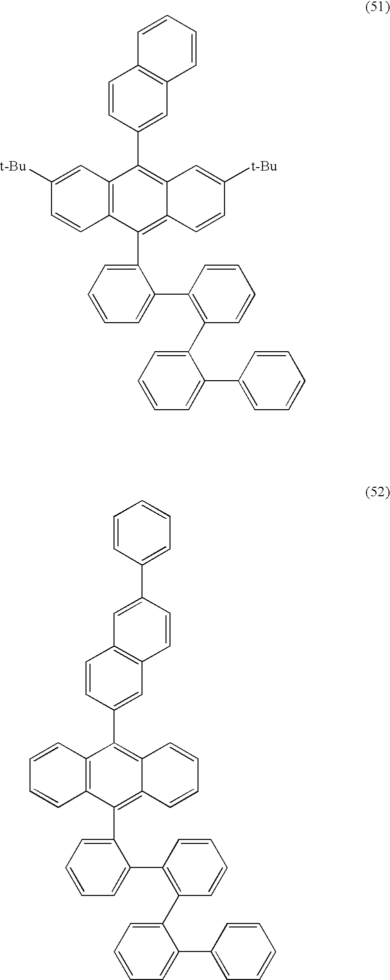

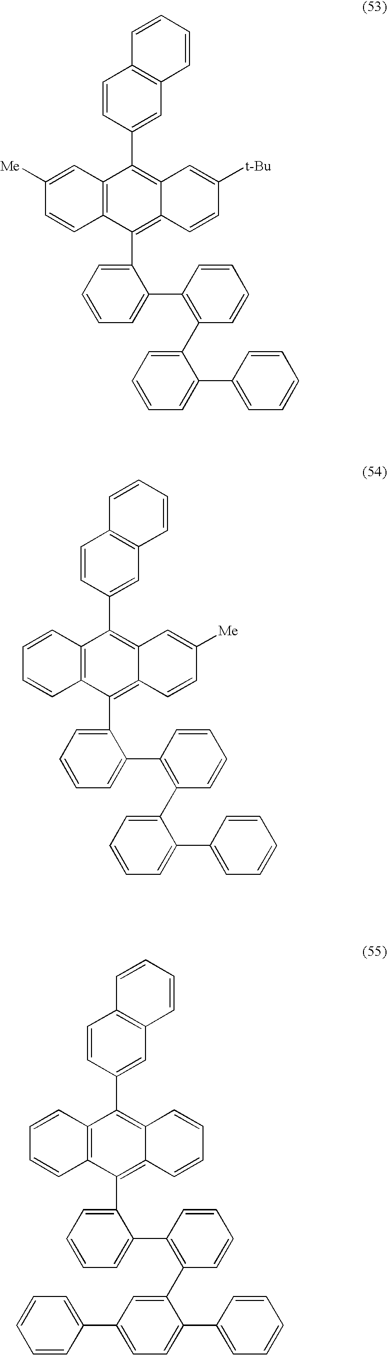

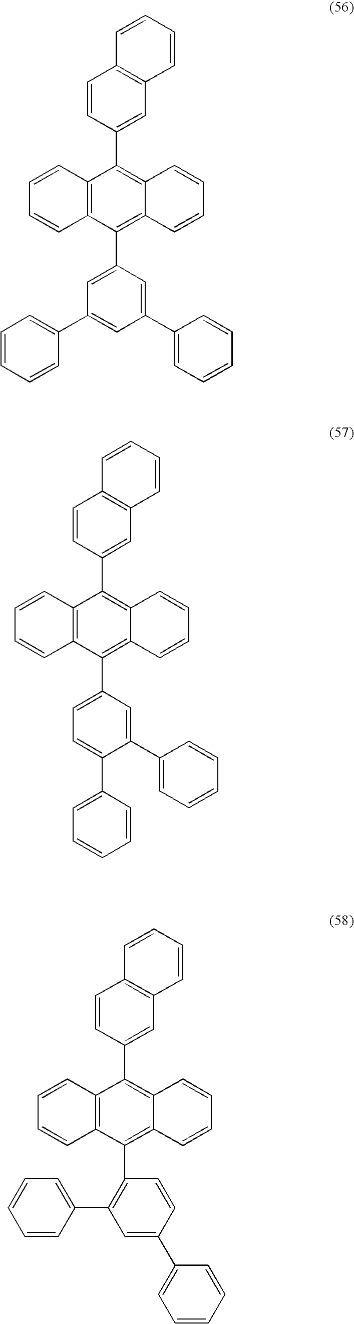

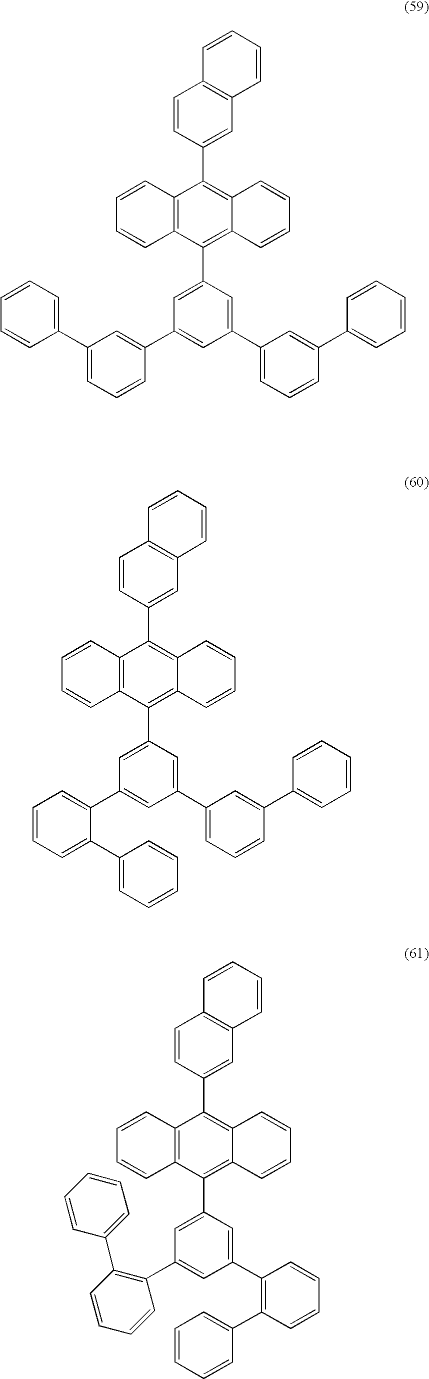

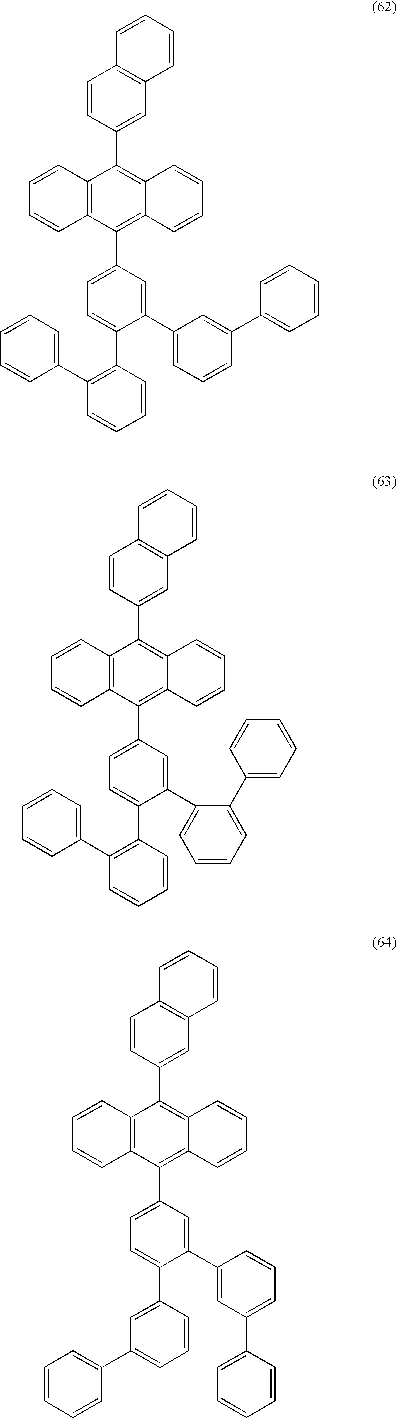

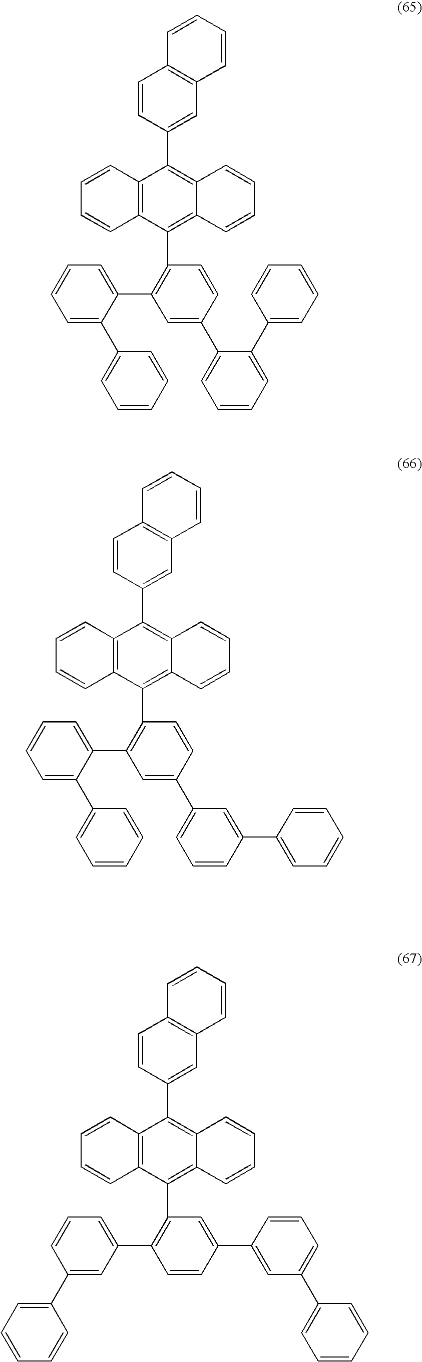

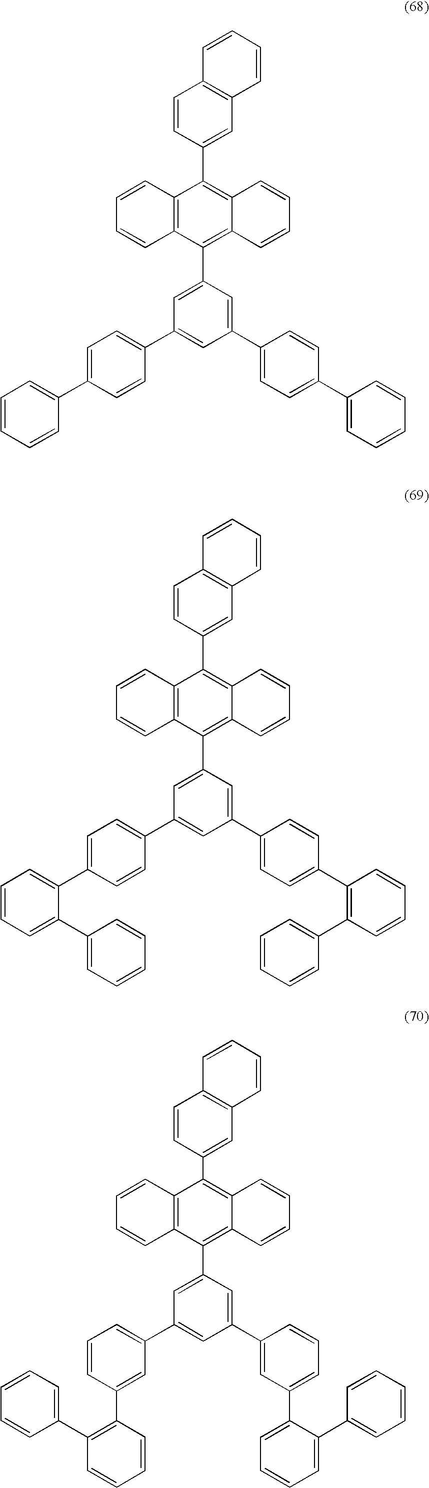

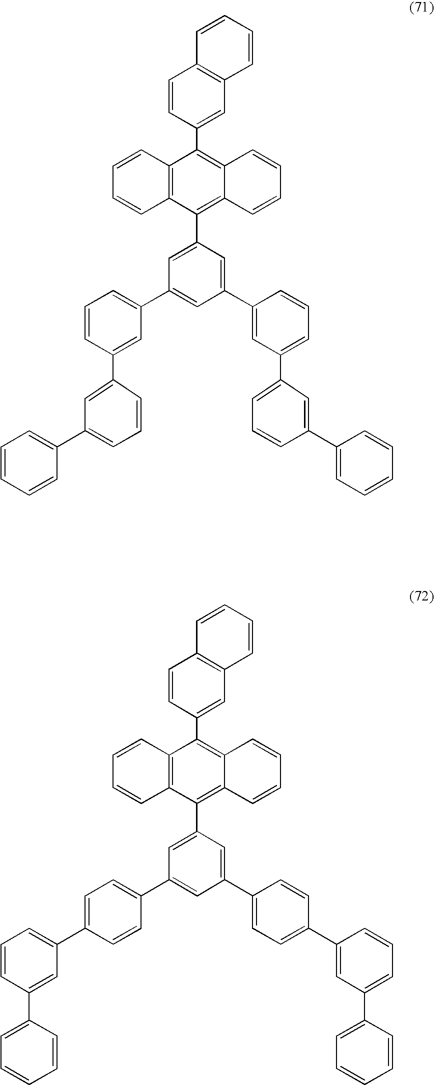

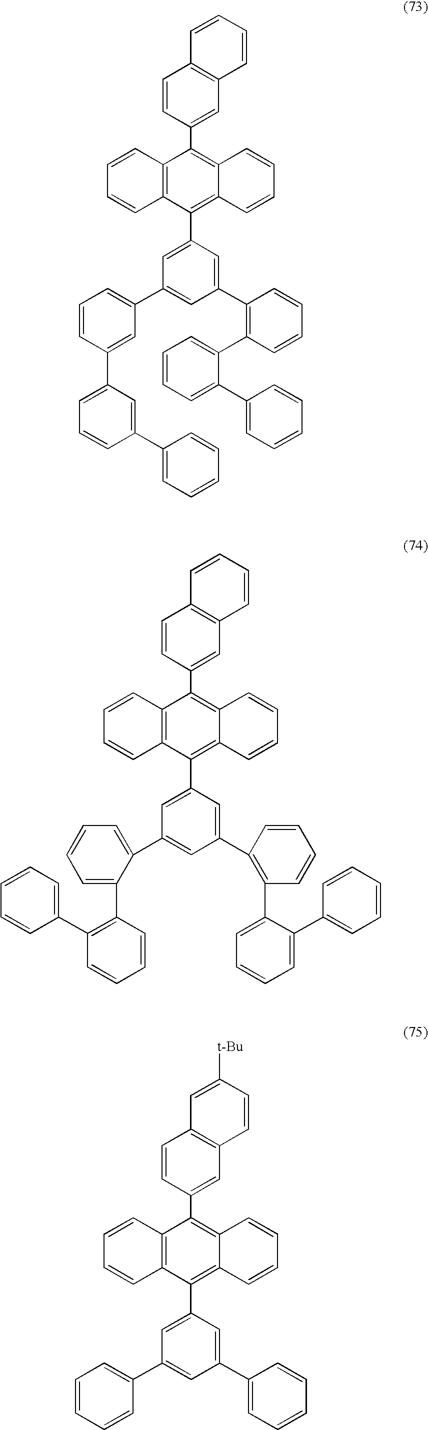

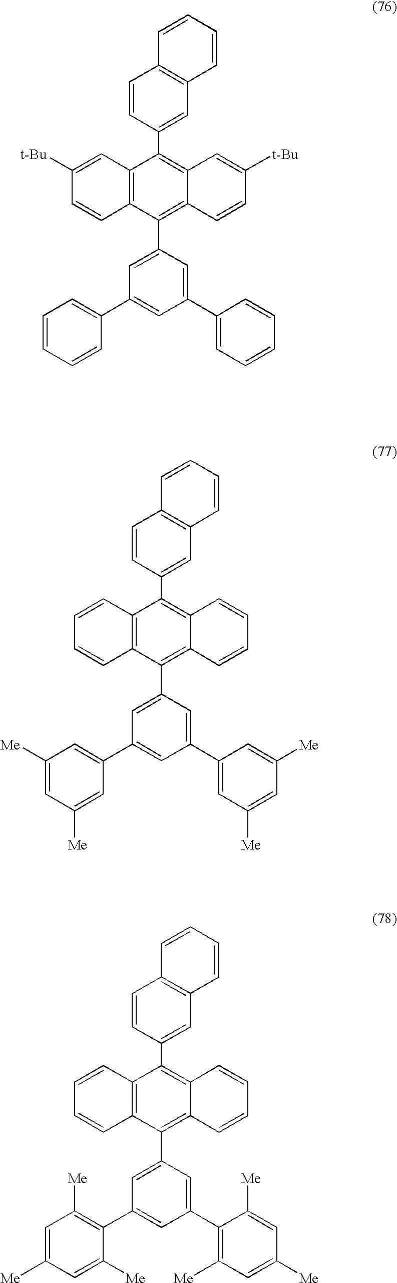

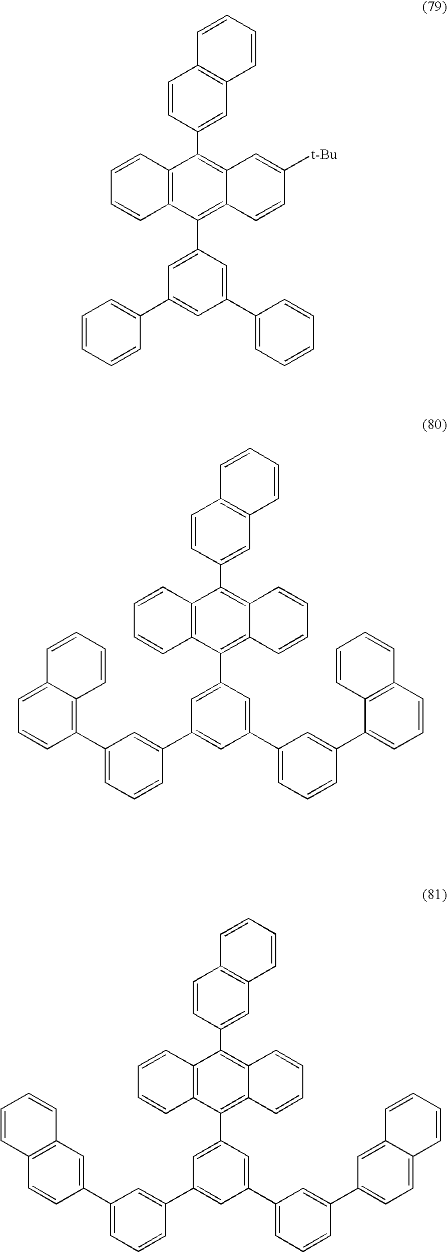

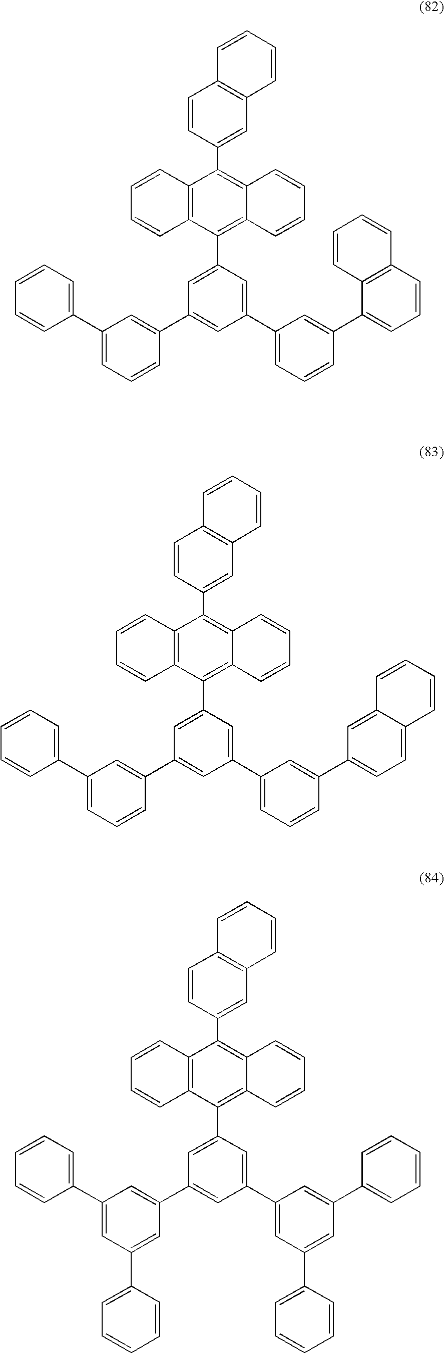

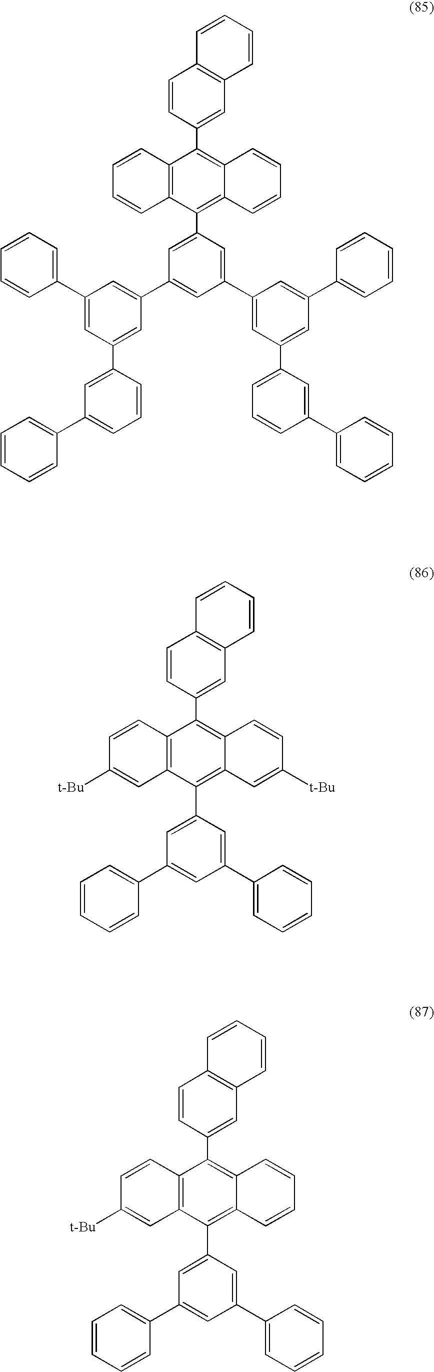

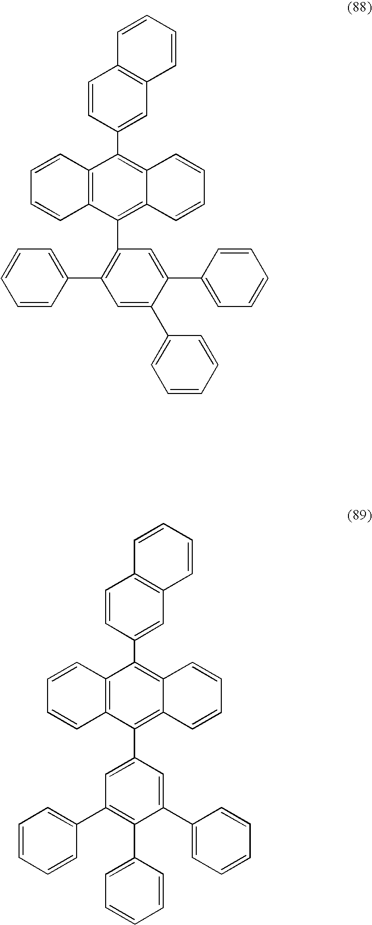

The preferred compounds out of the specific examples described above are the compounds (11), (12), (13), (14), (18), (23), (27), (28), (41), (44), (55), (59), (61), (68), (81) and (84). The particularly preferred compounds are the compounds (11), (12), (13), (14), (23), (27), (41), (44), (59), (61), (68) and (81).

The anthracene derivative represented by Formula (1) can be synthesized by making use of known synthetic processes such as Suzuki coupling reaction. The Suzuki coupling reaction is a process in which aromatic halide is subjected to coupling with aromatic boric acid using a palladium catalyst in the presence of a base. The specific example of a reaction route for obtaining the compound (1) by the above process is shown below: 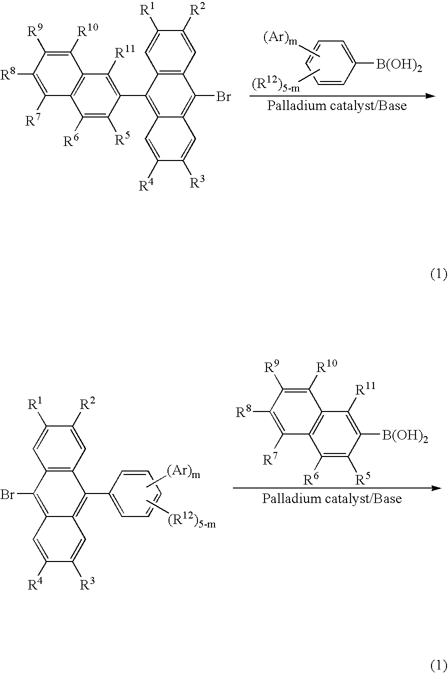
In the above formulas, R¹ to R¹² are the same as described above, and m is an integer of 1 to 3.

The specific examples of the palladium catalyst used in the above reaction are Pd(PPh₃)₄, PdCl₂(PPh₃)₂ and Pd(OAc)₂. The specific examples of the base used in the above reaction are sodium carbonate, potassium carbonate, cesium carbonate, sodium hydrogencarbonate, sodium hydroxide, potassium hydroxide, barium hydroxide, sodium ethoxide, sodium t-butoxide, sodium acetate, tripotassium phosphate and potassium fluoride. Further, the examples of the solvent used in the above reaction are benzene, toluene, xylene, N,N-dimethylformamide, tetrahydrofuran, diethyl ether, t-butyl methyl ether, 1,4-dioxane, methanol, ethanol and isopropyl alcohol. The above solvents can suitably be selected according to the structures of the aromatic halide and the aromatic boric acid which are reacted. The solvents may be used alone or in the form of a mixed solvent.

The anthracene derivative represented by Formula (1) is a compound having strong fluorescence in a solid state and can be used for emission of various colors, and it is particularly suited to emission of a blue color. These anthracene derivatives have an asymmetric molecular structure, and therefore they are liable to form an amorphous state in preparing an organic EL device. Further, these anthracene derivatives are excellent in a heat resistance and stable in applying an electric field.

The anthracene derivative represented by Formula (1) has a high quantum efficiency, a hole injection ability, a hole transport ability, an electron injection ability and an electron transport ability, and therefore it can effectively be used as an emission material for an emission layer. The anthracene derivative represented by Formula (1) is effective as a host emission material. These anthracene derivatives have a short emission wavelength and are excellent as a blue host emission material, but they can be used as well for emission of colors other than a blue color. When the anthracene derivative used in the present invention is used as a host material, energy transfer is efficiently carried out, and an emission device having a high efficiency and a long life is obtained.

The present invention relates to an organic EL device in which an emission layer comprises the anthracene derivative represented by Formula (1) as a host and comprises at least one selected from a perylene derivative, a borane derivative, a coumarin derivative, a pyran derivative, an iridium complex and a platinum complex as a dopant. The organic EL device of the present invention not only has a high efficiency and a long life but also has a low driving voltage and a high durability in storing and driving. The examples of the perylene derivative are 3,10-di(2,6-dimethylphenyl)perylene, 3,10-di(2,4,6-trimethylphenyl)perylene, 3,10-diphenylperylene, 3,4-diphenylperylene, 2,5,8,11-tetra-t-butylperylene, 3,4,9,10-tetraphenylperylene, 3-(1′-pyrenyl)-8,11-di(t-butyl)perylene, 3-(9′-anthryl)-8,11-di(t-butyl)perylene and 3,3′-bis(8,11-di(t-butyl)perylenyl).

The borane derivative is a compound represented by Formula (B) shown below: 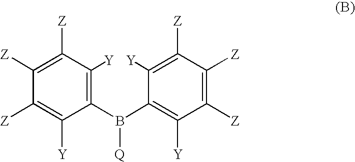
in Formula (B), Q is aryl having 6 to 50 carbon atoms or heteroaryl, and optional hydrogens in the above aryl having 6 to 50 carbon atoms and the heteroaryl may be replaced by cyano, alkyl having 1 to 12 carbon atoms, cycloalkyl having 3 to 12 carbon atoms or aryl having 6 to 24 carbon atoms; Y is alkyl having 1 to 12 carbon atoms, cycloalkyl having 3 to 24 carbon atoms, aryl having 6 to 50 carbon atoms or heteroaryl; Z is hydrogen, alkyl having 1 to 24 carbon atoms, cycloalkyl having 3 to 24 carbon atoms, aryl having 6 to 50 carbon atoms or heteroaryl; and Y and Z may be combined with each other between the adjacent groups to form a new ring.

The specific examples of the borane derivative are 1,8-diphenyl-10-(dimesitylboryl)anthracene, 9-phenyl-10-(dimethylboryl)anthracene, 4-(9-anthryl)dimesitylborylnaphthalne, 4-(10′-phenyl-9′-anthryl)dimesitylborylnaphthalne, 9-(dimesitylboryl)anthracene, 9-(4′-biphenylyl)-10-(dimesitylboryl)anthracene, 9-(4′-(N-carbazolyl)phenyl)-10-(dimesitylboryl)anthracene, 9-(3′-biphenyl)-10-(dimesitylboryl)anthracene, 9-(2′-biphenyl)-10-(dimesitylboryl)anthracene, 9-(dimesitylboryl)-10-[4-(10-dimesitylboryl-9-anthryl)phenyl]anthracene, 9-(dimesitylboryl)-10-[2,5-dimethyl-4-(10-dimesitylboryl-9-anthryl)phenyl]anthracene, 2,8-bis(dimesitylboryl)-6,6′,12,12′-tetraphenyl-6,12-dihydroindeno[1,2b]fluorene, 2,9-bis(dimesitylboryl)-6,6′,14,14′-tetraphenyl-6,14-dihydroindeno[1,2b]-benzo[i]fluorene, 2,9-bis(dimesitylboryl)-7,7′,14,12′-tetraphenyl-7,14-dihydrofluoreno[2,1a]fluorene, 9-(2′-cyanophenyl)-10-(dimesitylboryl)anthracene, 9-(3′-cyanophenyl)-10-(dimesitylboryl)anthracene, 9-(4′-cyanophenyl)-10-(dimesitylboryl)anthracene, 9-(6′-cyano-2′-phenylphenyl)-10-(dimesitylboryl)anthracene, 9-(5′-cyano-2′-phenylphenyl)-10-(dimesitylboryl)anthracene, 9-(4′-cyano-2′-phenylphenyl)-10-(dimesitylboryl)anthracene, 9-(6′-cyano-3′-phenylphenyl)-10-(dimesitylboryl)anthracene and 9-(5′-cyano-3′-phenylphenyl)-10-(dimesitylboryl)anthracene.

The specific examples of the coumarin derivative are coumarin-6, coumarin-6H, coumarin-30, coumarin-102, coumarin-110, coumarin-152, coumarin-334 and coumarin-480D.

The specific examples of the pyran derivative are DCM, DCJTB shown below and the like:

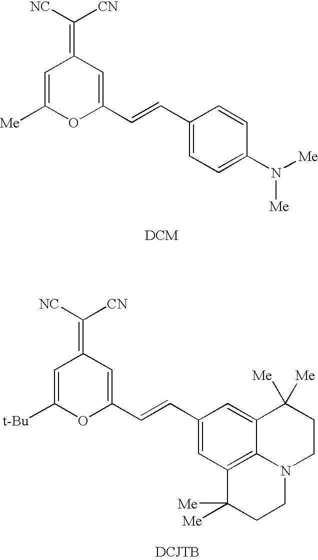

The specific examples of the iridium complex are Ir(ppy)₃ shown below and the like:

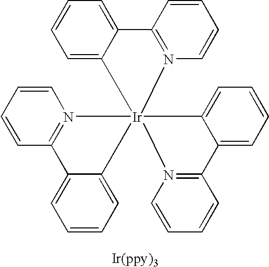

The specific examples of the platinum complex are PtOEP shown below and the like:

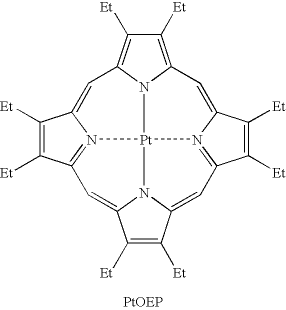

A use amount of the dopant is different depending on the dopants, and it may advisably be determined according to the characteristics of the dopants. A target for a use amount of the dopant is 0.001 to 50% by weight, preferably 0.1 to 10% by weight based on the whole part of the emission material.

The organic EL device of the present invention has structures of various modes. Fundamentally, it comprises a multilayer structure in which at least a hole transport layer, an emission layer and an electron transport layer are sandwiched between an anode and a cathode. The examples of the specific constitutions of the device are (1) anode/hole transport layer/emission layer/electron transport layer/cathode, (2) anode/hole injection layer/hole transport layer/emission layer/electron transport layer/cathode and (3) anode/hole injection layer/hole transport layer/emission layer/electron transport layer/electron injection layer/cathode.

Those optionally selected from compounds which can be used as an electron transport compound in a photoconductive material and compounds which can be used for an electron injection layer and an electron transport layer in an organic EL device can be used for an electron transport material and an electron injection material which are used for the organic EL device of the present invention.

The specific examples of the above electron transport compound are quinolinol base metal complexes, pyridine derivatives, phenanthroline derivatives, diphenylquinone derivatives, perylene derivatives, oxadiazole derivatives, thiophene derivatives, triazole derivatives, thiadiazole derivatives, metal complexes of oxine derivatives, quinoxaline derivatives, polymers of quinoxaline derivatives, benzoxazole compounds, gallium complexes, pyrazole derivatives, perfluorinated phenylene derivatives, triazine derivatives, pyrazine derivatives, benzoquinoline derivatives, imidazopyridine derivatives and borane derivatives.

The preferred examples of the electron transport compound are quinolinol base metal complexes, pyridine derivatives or phenanthroline derivatives. The specific examples of the quinolinol base metal complexes are tris(8-hydroxyquinoline)aluminum (hereinafter abbreviated as ALQ), bis(10-hydroxybenzo[h]quinoline)beryllium, tris(4-methyl-8-hydroxyquinoline)aluminum and bis(2-methyl-8-hydroxyquinoline)-(4-phenylphenol)aluminum. The specific examples of the pyridine derivatives are 2,5-bis(6′-(2′,2″-bipyridyl)-1,1-dimethyl-3,4-diphenylsilol (hereinafter abbreviated as PyPySPyPy), 9,10-di(2′,2″-bipyridyl)anthracene, 2,5-di(2′,2″-bipyridyl)thiophene and 2,5-di(3′,2″-bipyridyl)thiophene and 6′,6″-di(2-pyridyl)2,2′:4′,3″:2″,2′″-quaterpyridine. The specific examples of the phenanthroline derivatives are 4,7-diphenyl-1,10-phenanthroline, 2,9-dimethyl-4,7-diphenyl-1,10-phenanthroline, 9,10-di(1,10-phenanthroline-2-yl)anthracene, 2,6-di(1,10-phenanthroline-5-yl)pyridine, 1,3,5-tri(1,10-phenanthroline-5-yl)benzene and 9,9′-bis(1,10-phenanthroline-5-yl). In particular, use of the pyridine derivatives and the phenanthroline derivatives for the electron transport layer or the electron injection layer makes it possible to realize the low voltage and the high efficiency.

Optional compounds selected from compounds which have so far conventionally been used as a charge transport material for a hole in a photoconductive material and publicly known compounds which are used for a hole injection layer and a hole transport layer in an organic EL device can be used as a hole injection material and a hole transport material which are used for the organic EL device of the present invention. The specific examples thereof are carbazole derivatives, triarylamine derivatives and phthalocyanine derivatives. The specific examples of the carbazole derivatives are N-phenylcarbazole and polyvinylcarbazole. The specific examples of the triarylamine derivatives are polymers having aromatic tertiary amine in a principal chain or a side chain, 1,1-bis(4-di-p-tolylaminophenyl)cyclohexane, N,N′-diphenyl-N,N′-di(3-methylphenyl)-4,4′-diaminobiphenyl, N,N′-diphenyl-N,N′-dinaphthyl-4,4′-diaminobiphenyl (hereinafter abbreviated as NPD), 4,4′,4″-tris{N-(3-methylphenyl)-N-phenylamino}triphenylamine and star burst amine derivatives. The specific examples of the phthalocyanine derivatives are non-metal phthalocyanine and copper phthalocyanine.

The respective layers constituting the organic EL device of the present invention can be formed by making thin films from materials to constitute the respective layers by a vapor deposition method, a spin cast method or a cast method. A film thickness of the respective layers thus formed shall not specifically be restricted and can suitably be set up according to the properties, and it falls in a range of usually 2 nm to 5000 nm. The vapor deposition method is preferably adopted as a method for forming a thin film from the emission material in terms of the points that a homogeneous film is liable to be obtained and that pinholes are less liable to be formed. When the vapor deposition method is used to form a thin film, the vapor deposition conditions are varied depending on the kind of the emission material and a crystal structure and an aggregate structure which are targeted by a molecular cumulative film. The vapor deposition conditions are preferably set up in the ranges of usually a boat heating temperature of 50 to 400° C., a vacuum degree of 10⁻⁶ to 10⁻³ Pa, a deposition speed of 0.01 to 50 nm/second, a substrate temperature of −150 to +300° C. and a film thickness of 5 nm to 5 μm.

The organic EL device of the present invention is preferably supported by a substrate in any of the structures described above. The substrate may be any one as long as it has a mechanical strength, a heat stability and a transparency, and glass, a transparent plastic film and the like can be used. Metals, alloys, electroconductive compounds and mixtures thereof each having a work function of larger than 4 eV can be used for the anode material. The specific examples thereof are metals such as Au and the like, CuI, indium tin oxide (hereinafter abbreviated as ITO), SnO₂ and ZnO.

Metals, alloys, electroconductive compounds and mixtures thereof each having a work function of smaller than 4 eV can be used for the cathode material. The specific examples thereof are aluminum, calcium, magnesium, lithium, magnesium alloys and aluminum alloys. The specific examples of the alloys are aluminum/lithium fluoride, aluminum/lithium, magnesium/silver and magnesium/indium. At least one of the electrodes has preferably a light transmittance set to 10% or more in order to efficiently take out emission from the organic EL device. The electrodes are preferably controlled to a sheet resistance of several hundred Ω/square or less. The film thickness is set, though depending on the properties of the electrode materials, in a range of usually 10 nm to 1 μm, preferably 10 to 400 nm. Such electrodes can be produced by forming thin films from the electrode substances described above by methods such as vapor deposition and sputtering.

Next, a method for preparing an organic EL device comprising anode/hole injection layer/hole transport layer/anthracene derivative of the present invention+dopant (emission layer)/electron transport layer/cathode each described above shall be explained as one example of methods for preparing an organic EL device using the emission material of the present invention. A thin film of an anode material is formed on a suitable substrate by a vapor deposition method to prepare an anode, and then the thin films of a hole injection layer and a hole transport layer are formed on the above anode. The emission material of the present invention and a dopant are codeposited thereon to form a thin film to thereby obtain an emission layer, and an electron transport layer is formed on the above emission layer. Further, a thin film comprising a material for a cathode is formed thereon by a vapor deposition method to prepare a cathode, whereby the intended organic EL device is obtained. In preparing the organic EL device described above, it can be prepared as well in the order of a cathode, an electron transport layer, an emission layer, a hole transport layer, a hole injection layer and an anode by upsetting the preparing order.

When applying DC voltage to the organic EL device thus obtained, it is applied with the polarity of the anode set to + and that of the cathode set to −, and when applying a voltage of 2 to 40 V, emission can be observed from the transparent or translucent electrode sides (anode or cathode and both). Also, when applying AC voltage to the above organic EL device, emission is observed as well. The waveform of the alternating current applied may be optional.

### EXAMPLES

The present invention shall be explained in further details with reference to examples.

### Example 1 Synthesis of Compound (56)

9-Bromo-10-(m-terphenyl)anthracene 4.85 g and β-naphthyleneboronic acid 2.58 g were dissolved in a mixed solvent 100 ml (toluene/ethanol=4/1) of toluene and ethanol under nitrogen atmosphere, and tetrakis(triphenylphosphine)palladium (0) 0.58 g was added thereto, followed by stirring the solution for 5 minutes. Then, a sodium carbonate aqueous solution 10 ml of 2M was added thereto, and the solution was refluxed for 3 hours. After finishing heating, the reaction liquid was cooled down to separate an organic layer, and this was washed with saturated brine and then dried on anhydrous magnesium sulfate. A solid matter obtained by removing the desiccant and distilling off the solvent under reduced pressure was subjected to column refining (solvent: heptane/toluene=3/1) with silica gel, and then it was refined by sublimation to obtain 3.5 g of the targeted compound. The structure of the compound (56) was confirmed by an MS spectrum and NMR measurement. The other physical properties are shown below. Melting point: 304° C., crystallization temperature: 185° C. (measuring equipment: UNIX-DSC7, manufactured by Perkin Elmer Co., Ltd.; measuring conditions: cooling speed 200° C./min., heating speed 40° C./min.), fluorescent quantum efficiency/toluene solution: 0.8 (measuring equipment: V-560, manufactured by JASCO Corporation and FP-777W, manufactured by JASCO Corporation)

### Example 2 Synthesis of Compound (23)

9-Bromo-10-(β-naphthyl)anthracene 3.83 g and m-quaterphenyl-3-boronic acid 3.85 g were dissolved in a mixed solvent 100 ml (toluene/ethanol=4/1) of toluene and ethanol under nitrogen atmosphere, and tetrakis(triphenylphosphine)palladium (0) 0.58 g was added thereto, followed by stirring the solution for 5 minutes. Then, a sodium carbonate aqueous solution 10 ml of 2M was added thereto, and the solution was refluxed for 10 hours. After finishing heating, the reaction liquid was cooled down to separate an organic layer, and this was washed with saturated brine and then dried on anhydrous magnesium sulfate. A solid matter obtained by removing the desiccant and distilling off the solvent under reduced pressure was subjected to column refining (solvent: heptane/toluene=3/1) with silica gel, and then it was refined by sublimation to obtain 4 g of the targeted compound. The structure of the compound (23) was confirmed by an MS spectrum and NMR measurement. Melting point: 220° C.

### Example 3 Synthesis of Compound (27)

9-Bromo-10-(β-naphthyl)anthracene 3.83 g and o-quaterphenyl-3-boronic acid 3.85 g were dissolved in a mixed solvent 100 ml (toluene/ethanol=4/1) of toluene and ethanol under nitrogen atmosphere, and tetrakis(triphenylphosphine)palladium (0) 0.58 g was added thereto, followed by stirring the solution for 5 minutes. Then, a sodium carbonate aqueous solution 10 ml of 2M was added thereto, and the solution was refluxed for 10 hours. After finishing heating, the reaction liquid was cooled down to separate an organic layer, and this was washed with saturated brine and then dried on anhydrous magnesium sulfate. A solid matter obtained by removing the desiccant and distilling off the solvent under reduced pressure was subjected to column refining (solvent: heptane/toluene=3/1) with silica gel, and then it was refined by sublimation to obtain 3 g of the targeted compound. The structure of the compound (27) was confirmed by an MS spectrum and NMR measurement. Melting point: 210° C.

The other emission materials of the present invention can be synthesized by suitably selecting the raw material compounds by methods according to the synthetic examples described above.

### Example 4

A glass substrate (manufactured by Tokyo Sanyo Vacuum Co., Ltd.) of 25 mm×75 mm×1.1 mm on which ITO was deposited in a thickness of 150 nm was used for a transparent supporting substrate. This transparent supporting substrate was fixed on a substrate holder of a commercial vacuum deposition apparatus (manufactured by ULVAC KIKO, Inc.), and installed therein were a molybdenum-made depositing boat containing copper phthalocyanine, a molybdenum-made depositing boat containing NPD, a molybdenum-made depositing boat containing the compound (56), a molybdenum-made depositing boat containing a perylene derivative represented by Formula (90) shown below, a molybdenum-made depositing boat containing ALQ, a molybdenum-made depositing boat containing lithium fluoride and a tungsten-made depositing boat containing aluminum. A pressure of the vacuum chamber was reduced down to 1×10⁻³ Pa, and the depositing boat containing copper phthalocyanine was heated to deposit copper phthalocyanine so that a film thickness of 20 nm was obtained to thereby form a hole injection layer. Then, the depositing boat containing NDP was heated to deposit NDP so that a film thickness of 30 nm was obtained to thereby form a hole transport layer. Next, the molybdenum-made depositing boat containing the compound (56) and the molybdenum-made depositing boat containing the perylene derivative represented by Formula (90) were heated to codeposit them so that a film thickness of 35 nm was obtained to thereby form an emission layer. In this case, the doping concentration was about 1% by weight. Then, the depositing boat containing ALQ was heated to deposit ALQ so that a film thickness of 15 nm was obtained to thereby form an electron transport layer. The above depositing rates were 0.1 to 0.2 nm/second. Thereafter, the depositing boat containing lithium fluoride was heated to deposit lithium fluoride at a depositing rate of 0.003 to 0.01 nm/second so that a film thickness of 0.5 nm was obtained, and then the depositing boat containing aluminum was heated to deposit aluminum at a depositing rate of 0.2 to 0.5 nm/second so that a film thickness of 100 nm was obtained, whereby an organic EL device was obtained. A DC voltage of about 4.7 V was applied with the ITO electrode used as an anode and the lithium fluoride/aluminum electrode used as a cathode to find that a current of about 1.8 mA/cm² passed to obtain emission of a blue color having an emission efficiency of 4 lm/W and a wavelength of 468 nm. Further, the half lifetime of the device was 410 hours at an initial luminance of 1800 cd/m² when it was driven at a constant current of 50 mA/cm².

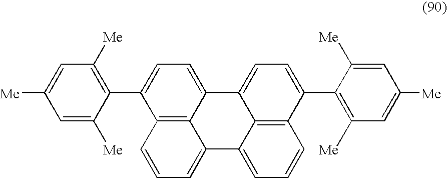

### Example 5

An organic EL device was obtained by a method corresponding to Example 4, except that a borane derivative represented by Formula (91) shown below was substituted for the compound (90) used in Example 4. A DC voltage of about 5 V was applied with the ITO electrode used as an anode and the lithium fluoride/aluminum electrode used as a cathode to find that a current of about 1.5 mA/cm² passed to obtain emission of a blue color having an emission efficiency of 5 lm/W and a wavelength of 472 nm. Further, the half lifetime of the device was 220 hours at an initial luminance of 3200 cd/M² when it was driven at a constant current of 50 mA/cm².

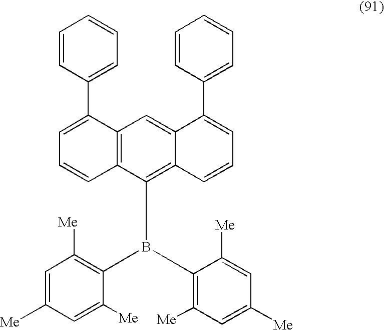

### Example 6

An organic EL device was obtained by a method corresponding to Example 4, except that the compound (23) was substituted for the compound (56) used in Example 4. A DC voltage of about 4.5 V was applied with the ITO electrode used as an anode and the lithium fluoride/aluminum electrode used as a cathode to find that a current of about 1.9 mA/cm² passed to obtain emission of a blue color having an emission efficiency of 3.8 lm/W and a wavelength of 468 nm. Further, the half lifetime of the device was 400 hours at an initial luminance of 1780 cd/m² when it was driven at a constant current of 50 mA/cm².

### Example 7

An organic EL device was obtained by a method corresponding to Example 4, except that PyPySPyPy was substitute for ALQ used in Example 4. A DC voltage of about 3 V was applied with the ITO electrode used as an anode and the lithium fluoride/aluminum electrode used as a cathode to find that a current of about 1 mA/cm2 passed to obtain emission of a blue color having an emission efficiency of 6.5 lm/W and a wavelength of 467 nm. Further, the half lifetime of the device was 230 hours at an initial luminance of 2600 cd/m² when it was driven at a constant current of 50 mA/cm².

### Example 8

An organic EL device was obtained by a method corresponding to Example 7, except that the borane derivative represented by Formula (91) described above was substituted for the compound (90) used in Example 7. A DC voltage of about 3.2 V was applied with the ITO electrode used as an anode and the lithium fluoride/aluminum electrode used as a cathode to find that a current of about 1 mA/cm² passed to obtain emission of a blue color having an emission efficiency of 8 lm/W and a wavelength of 473 nm. Further, the half lifetime of the device was 100 hours at an initial luminance of 4700 cd/m² when it was driven at a constant current of 50 mA/cm².

### Example 9

An organic EL device was obtained by a method corresponding to Example 6, except that PyPySPyPy was substitute for ALQ used in Example 6. A DC voltage of about 3.1 V was applied with the ITO electrode used as an anode and the lithium fluoride/aluminum electrode used as a cathode to find that a current of about 1.2 mA/cm² passed to obtain emission of a blue color having an emission efficiency of 6 lm/W and a wavelength of 468 nm. Further, the half lifetime of the device was 240 hours at an initial luminance of 2620 cd/m² when it was driven at a constant current of 50 mA/cm².

### Example 10

An organic EL device was obtained by a method corresponding to Example 8, except that the compound (27) was substituted for the compound (56) used in Example 8. A DC voltage of about 3.4 V was applied with the ITO electrode used as an anode and the lithium fluoride/aluminum electrode used as a cathode to find that a current of about 1.1 mA/cm² passed to obtain emission of a blue color having an emission efficiency of 7.8 lm/W and a wavelength of 473 nm. Further, the half lifetime of the device was 105 hours at an initial luminance of 4670 cd/m2 when it was driven at a constant current of 50 mA/cm².

### Comparative Example 1

A glass substrate (manufactured by Tokyo Sanyo Vacuum Co., Ltd.) of 25 mm×75 mm×1.1 mm on which ITO was deposited in a thickness of 150 nm was used for a transparent supporting substrate. This transparent supporting substrate was fixed on a substrate holder of a commercial vacuum deposition apparatus (manufactured by ULVAC KIKO, Inc.), and installed therein were a molybdenum-made depositing boat containing copper phthalocyanine, a molybdenum-made depositing boat containing NPD, a molybdenum-made depositing boat containing an anthracene derivative represented by Formula (92) shown below, a molybdenum-made depositing boat containing ALQ, a molybdenum-made depositing boat containing lithium fluoride and a tungsten-made depositing boat containing aluminum. A pressure of the vacuum chamber was reduced down to 1×10⁻³ Pa, and the depositing boat containing copper phthalocyanine was heated to deposit copper phthalocyanine so that a film thickness of 20 nm was obtained to thereby form a hole injection layer. Then, the depositing boat containing NDP was heated to deposit NDP so that a film thickness of 30 nm was obtained to thereby form a hole transport layer. Next, the molybdenum-made depositing boat containing the compound (92) was heated to deposit it so that a film thickness of 35 nm was obtained to thereby form an emission layer. Then, the depositing boat containing ALQ was heated to deposit ALQ so that a film thickness of 15 nm was obtained to thereby form an electron transport layer. The above depositing rates were 0.1 to 0.2 nm/second. Thereafter, the depositing boat containing lithium fluoride was heated to deposit lithium fluoride at a depositing rate of 0.003 to 0.01 nm/second so that a film thickness of 0.5 nm was obtained, and then the depositing boat containing aluminum was heated to deposit aluminum at a depositing rate of 0.2 to 0.5 nm/second so that a film thickness of 100 nm was obtained, whereby an organic EL device was obtained. A DC voltage of about 6 V was applied with the ITO electrode used as an anode and the lithium fluoride/aluminum electrode used as a cathode to find that a current of about 5 mA/cm² passed to obtain emission of a blue color having an emission efficiency of 1.2 lm/W and a wavelength of 440 nm. Further, the half lifetime of the device was 50 hours at an initial luminance of 950 cd/m² when it was driven at a constant current of 50 mA/cm².

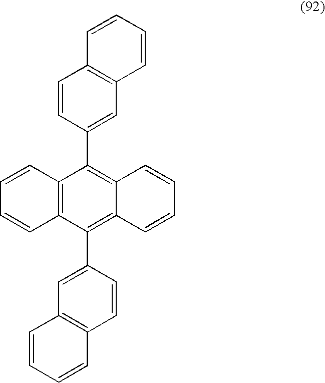

### Comparative Example 2

An organic EL device was obtained by a method corresponding to Comparative Example 1, except that PyPySPyPy was substitute for ALQ used in Comparative Example 1. A DC voltage of about 4.2 V was applied with the ITO electrode used as an anode and the lithium fluoride/aluminum electrode used as a cathode to find that a current of about 5.1 mA/cm² passed to obtain emission of a blue color having an emission efficiency of 1.5 lm/W and a wavelength of 441 nm. Further, the half lifetime of the device was 31 hours at an initial luminance of 1000 cd/m2 when it was driven at a constant current of 50 mA/cm².

### Comparative Example 3

An organic EL device was obtained by a method corresponding to Example 7, except that the anthracene derivative represented by Formula (92) described above was substituted for the compound (56) used in Example 7. A DC voltage of about 4 V was applied with the ITO electrode used as an anode and the lithium fluoride/aluminum electrode used as a cathode to find that a current of about 2 mA/cm² passed to obtain emission of a blue color having an emission efficiency of 4 lm/W and a wavelength of 464 nm. Further, the half lifetime of the device was 75 hours at an initial luminance of 2400 cd/M2 when it was driven at a constant current of 50 MA/cm².

### Comparative Example 4

An organic EL device was obtained by a method corresponding to Example 4, except that an anthracene derivative represented by Formula (93) shown below was substituted for the compound (56) used in Example 4. A DC voltage of about 5 V was applied with the ITO electrode used as an anode and the lithium fluoride/aluminum electrode used as a cathode to find that a current of about 3.5 mA/cm² passed to obtain emission of a blue color having an emission efficiency of 2 lm/W and a wavelength of 467 nm. Further, the half lifetime of the device was 125 hours at an initial luminance of 1400 cd/m2 when it was driven at a constant current of 50 mA/cm².

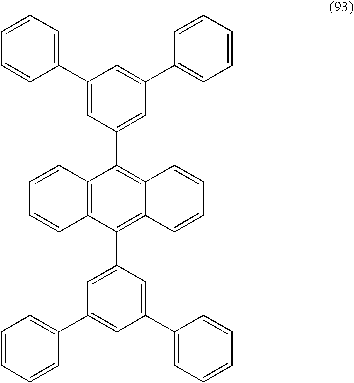

### Comparative Example 5

An organic EL device was obtained by a method corresponding to Example 7, except that an amine-containing styryl derivative represented by Formula (94) shown below was substituted for the compound (90) used in Example 7. A DC voltage of about 4 V was applied with the ITO electrode used as an anode and the lithium fluoride/aluminum electrode used as a cathode to find that a current of about 1.8 mA/cm² passed to obtain emission of a blue color having an emission efficiency of 5.2 lm/W and a wavelength of 455 nm. Further, the half lifetime of the device was 10 hours at an initial luminance of 2800 cd/m² when it was driven at a constant current of 50 mA/cm².

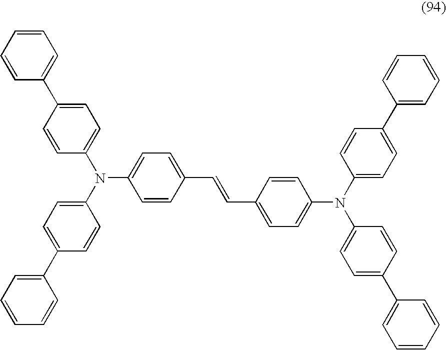

### Comparative Example 6

An organic EL device was obtained by a method corresponding to Example 7, except that an amine-containing styryl derivative represented by Formula (95) shown below was substituted for the compound (90) used in Example 7. A DC voltage of about 4.2 V was applied with the ITO electrode used as an anode and the lithium fluoride/aluminum electrode used as a cathode to find that a current of about 4.7 mA/cm² passed to obtain emission of a blue color having an emission efficiency of 1.6 lm/W and a wavelength of 448 nm. Further, the half lifetime of the device was 8 hours at an initial luminance of 1000 cd/M² when it was driven at a constant current of 50 mA/cm².

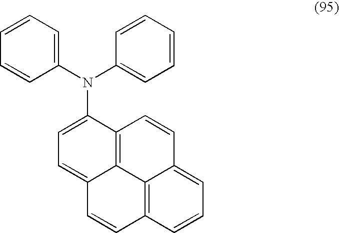

### INDUSTRIAL APPLICABILITY

The anthracene derivative represented by Formula (1) has a high fluorescent quantum efficiency and a high heat resistance, and therefore it is suited as a compound used for an emission layer of an organic EL device, particularly as a host for an emission layer. The anthracene derivative represented by Formula (1) can be used for emission of various colors, and it is particularly excellent in emission of a blue color. An organic EL device having a high emission efficiency, a low driving voltage, an excellent heat resistance and a long life can be obtained by using the above emission material as a host for an emission layer and using at least one of a perylene derivative, a borane derivative, a coumarin derivative, a pyran derivative, an iridium complex and a platinum complex as a dopant. Use of the organic EL device of the present invention makes it possible to prepare display devices having a high performance such as full color displays.

1. An organic electroluminescent device which is sandwiched between an anode and a cathode and which comprises at least a hole transport layer, an emission layer and an electron transport layer, wherein the emission layer comprises an anthracene derivative represented by Formula (1) shown below as a host and at least one selected from a perylene derivative, a borane derivative, a coumarin derivative, a pyran derivative, an iridium complex and a platinum complex as a dopant: 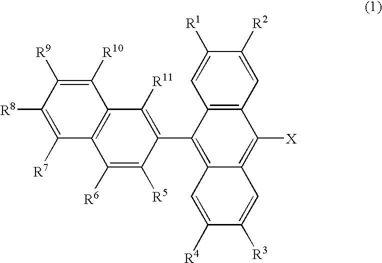
wherein R¹ to R⁴ are independently hydrogen or alkyl having 1 to 12 carbon atoms, and optional —CH₂— in the above alkyl having 1 to 12 carbon atoms may be replaced by —O—; R⁵ to R¹¹ are independently hydrogen, alkyl having 1 to 12 carbon atoms, cycloalkyl having 3 to 12 carbon atoms or aryl having 6 to 12 carbon atoms, wherein optional —CH₂— in the above alkyl having 1 to 12 carbon atoms may be replaced by —O— or arylene having 6 to 12 carbon atoms; optional hydrogens in the above cycloalkyl having 3 to 12 carbon atoms may be replaced by alkyl having 1 to 12 carbon atoms or aryl having 6 to 12 carbon atoms; and optional hydrogens in the above aryl having 6 to 12 carbon atoms may be replaced by alkyl having 1 to 12 carbon atoms, cycloalkyl having 3 to 12 carbon atoms, aryl having 6 to 12 carbon atoms or non-condensed aryl having 12 to 18 carbon atoms; and X is one selected from the group of groups represented by Formulas (2-1) to (2-15) shown below: 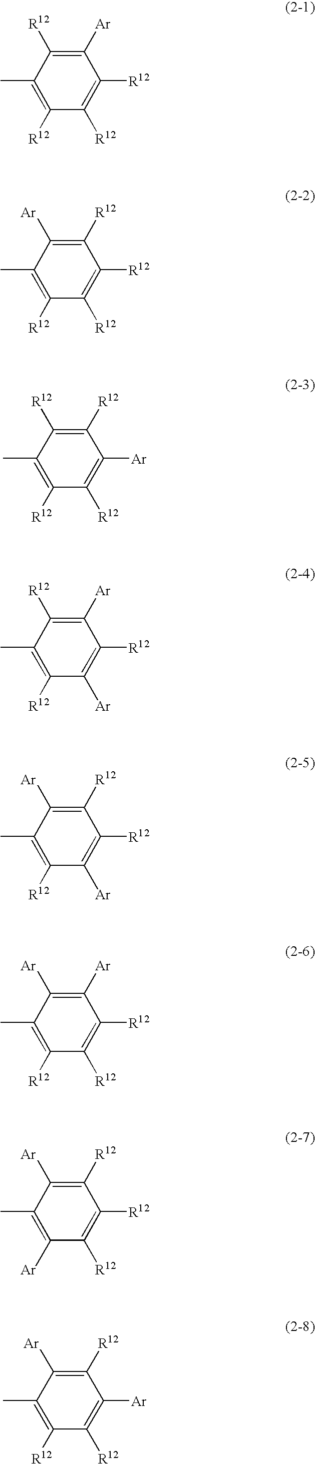 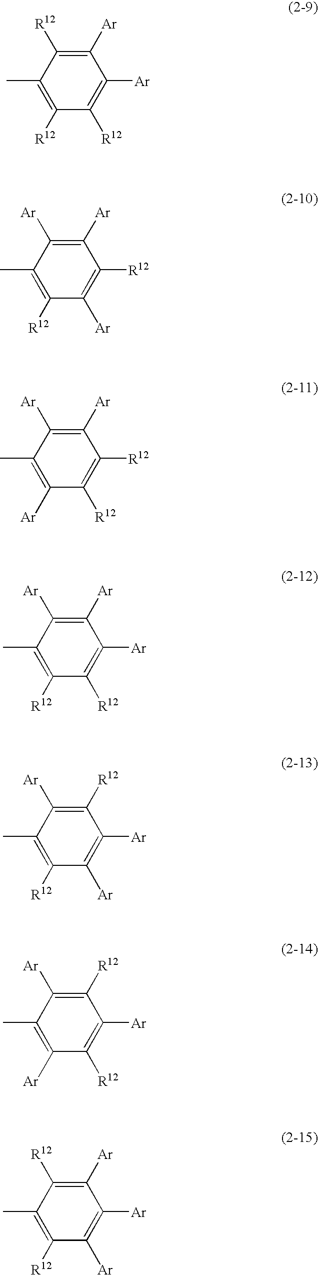
in Formulas (2-1) to (2-15), R¹² is independently the same as that represented by R¹ to R⁴ in Formula (1); and Ar is independently non-condensed aryl represented by Formula (3): 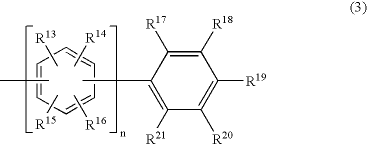
wherein n is an integer of 0 to 5; R¹³ to R²¹ are independently hydrogen, alkyl having 1 to 12 carbon atoms or aryl having 6 to 12 carbon atoms; optional —CH₂— in the above alkyl having 1 to 12 carbon atoms may be replaced by —O—, and optional hydrogens in the above aryl having 6 to 12 carbon atoms may be replaced by alkyl having 1 to 12 carbon atoms, cycloalkyl having 3 to 12 carbon atoms or aryl having 6 to 12 carbon atoms.

2. The organic electroluminescent device as described in claim 1, wherein the emission layer comprises as a host, the anthracene derivative in which R¹ to R⁴ in Formula (1) are independently hydrogen, methyl or t-butyl; R⁵ to R¹¹ are independently hydrogen, methyl, t-butyl, phenyl, 1-naphthyl, 2-naphthyl, 4-t-butylphenyl or m-terphenyl-5′-yl; X is one selected from the group of the groups represented by Formulas (2-1) to (2-15); and in Formulas (2-1) to (2-15), R¹² is independently hydrogen, methyl or t-butyl.

3. The organic electroluminescent device as described in claim 1, wherein the emission layer comprises as a host, the anthracene derivative in which R¹ to R⁴ in Formula (1) are hydrogen; R⁵ to R¹¹ are independently hydrogen, phenyl, 1-naphthyl, 2-naphthyl or m-terphenyl-5′-yl; X is one selected from the group of the groups represented by Formulas (2-1) to (2-15); and in Formulas (2-1) to (2-15), R¹² is hydrogen.

4. The organic electroluminescent device as described in claim 1, wherein the emission layer comprises as a host, the anthracene derivative in which R¹ to R⁴ in Formula (1) are hydrogen; R⁵ to R¹¹ are independently hydrogen, phenyl, 1-naphthyl, 2-naphthyl or m-terphenyl-5′-yl; and X is one selected from the group of the groups represented by Formulas (2-1), (2-2), (2-4) to (2-6) and (2-10) shown below: 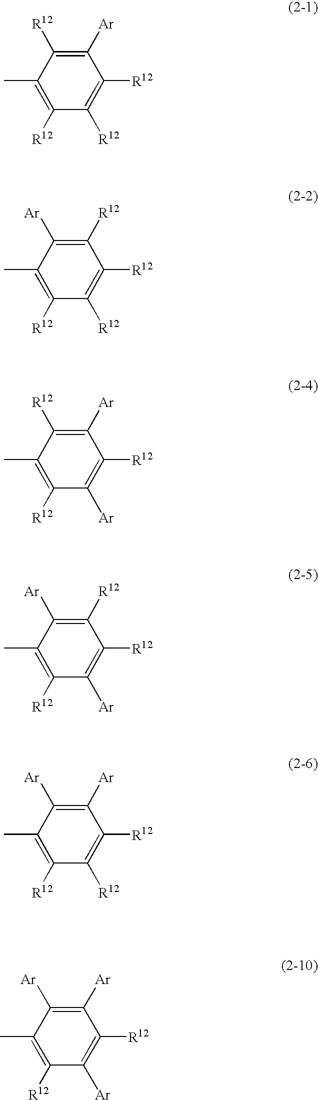
in Formulas (2-1), (2-2), (2-4) to (2-6) and (2-10), R¹² is hydrogen; and Ar independently one selected from the group of groups represented by Formulas (4-1) to (4-16) shown below:

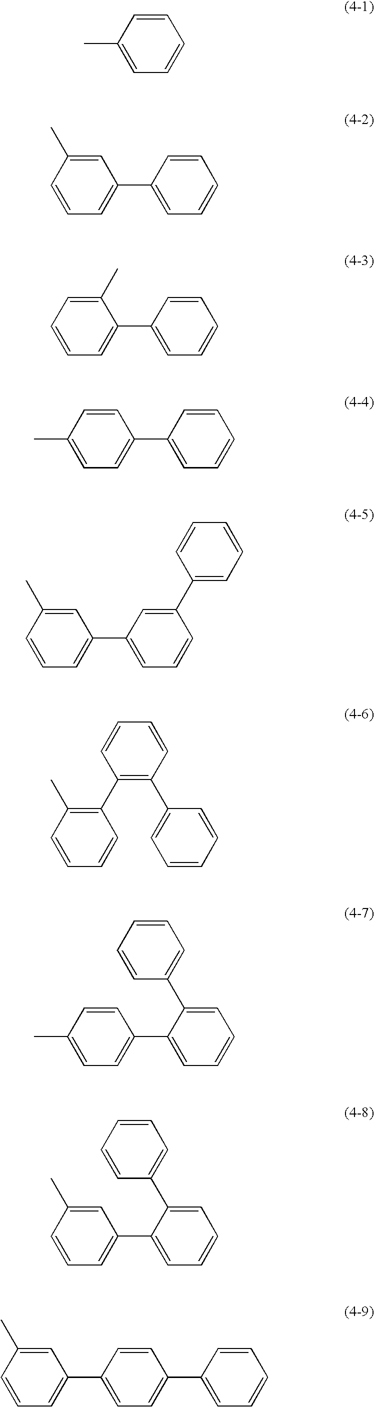

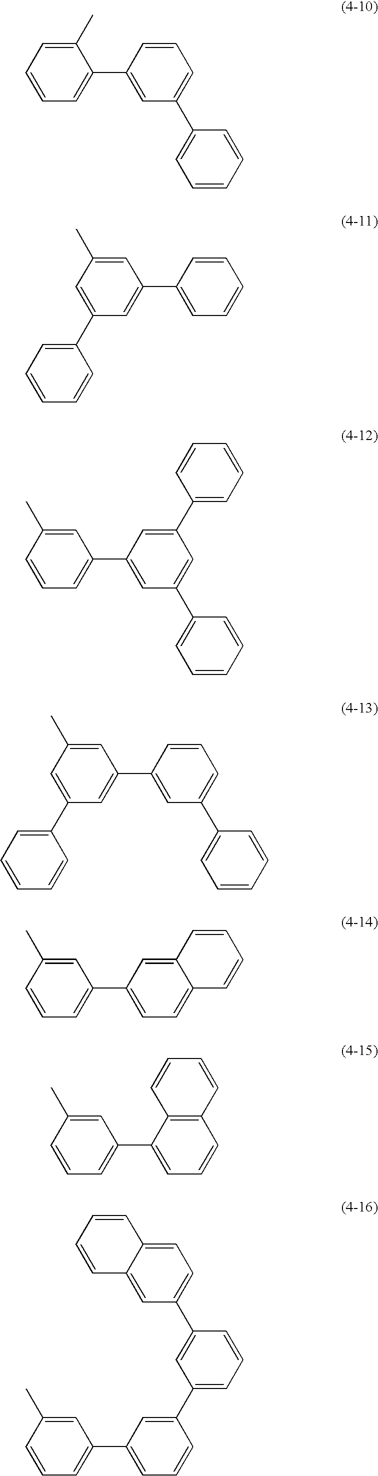

5. The organic electroluminescent device as described in claim 1, wherein the emission layer comprises as a host, the anthracene derivative in which R¹ to R⁴ in Formula (1) are hydrogen; R⁵ to R¹¹ are independently hydrogen, phenyl, 1-naphthyl, 2-naphthyl or m-terphenyl-5′-yl; and X is one selected from the group of the groups represented by Formulas (2-1), (2-2), (2-4) to (2-6) and (2-10) shown below: 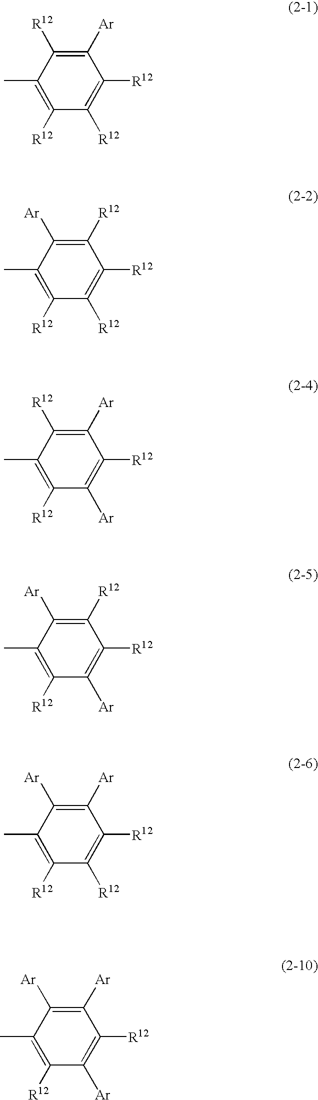
in Formulas (2-1), (2-2), (2-4) to (2-6) and (2-10), R¹² is hydrogen; and Ar is independently one selected from the group of groups represented by Formulas (4-1) to (4-10) and (4-14) to (4-16) shown below:

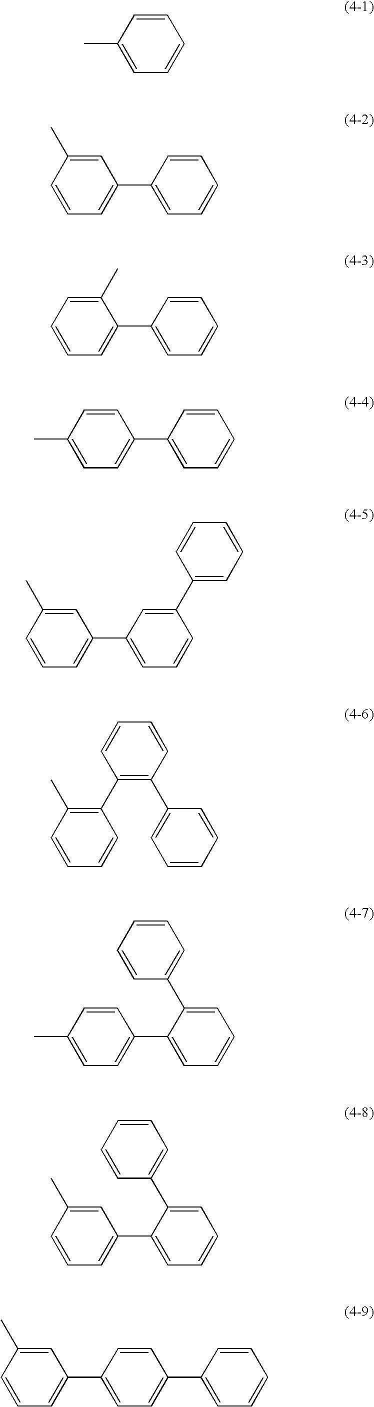

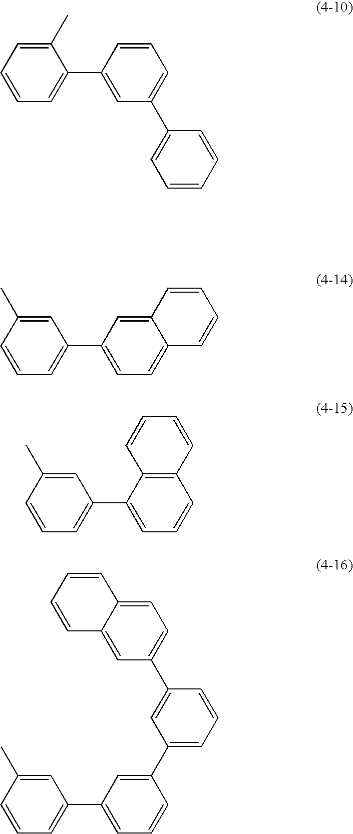

6. The organic electroluminescent device as described in claim 1, wherein the emission layer comprises as a host, the anthracene derivative in which R¹ to R⁴ in Formula (1) are hydrogen; R⁵ to R¹¹ are independently hydrogen, phenyl, 1-naphthyl, 2-naphthyl or m-terphenyl-5′-yl; and X is one selected from the group of the groups represented by Formulas (2-1), (2-2), (2-4) and (2-5) shown below: 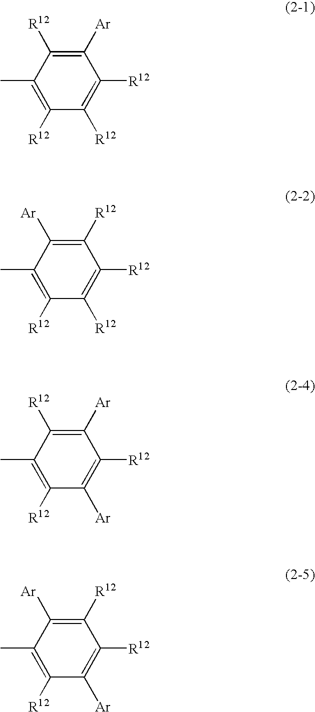
in Formulas (2-1), (2-2), (2-4) and (2-5), R¹² is hydrogen; and Ar is independently one selected from the group of groups represented by Formulas (4-1) to (4-10) and (4-14) to (4-16) shown below:

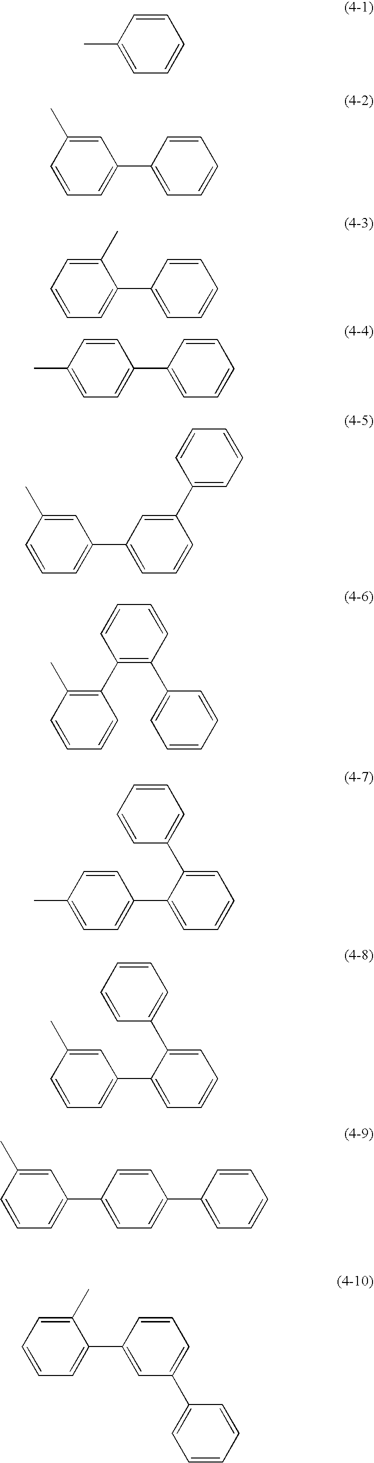

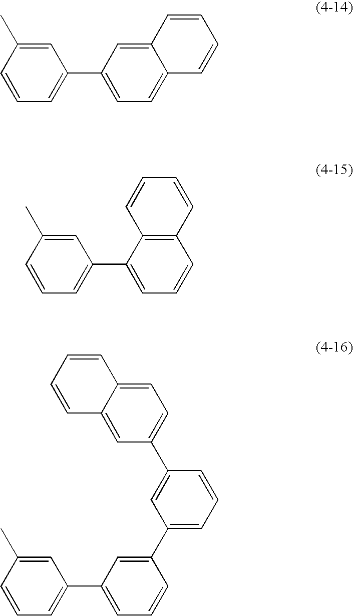

7. The organic electroluminescent device as described in claim 1, wherein the electron transport layer comprises a quinolyl base metal complex.

8. The organic electroluminescent device as described in claim 1, wherein the electron transport layer comprises at least one of a pyridine derivative and a phenanthroline derivative.

9. The organic electroluminescent device as described in claim 7, wherein the emission layer comprises the perylene derivative as a dopant.

10. The organic electroluminescent device as described in claim 8, wherein the emission layer comprises the perylene derivative as a dopant.

11. The organic electroluminescent device as described in claim 7, wherein the emission layer comprises the borane derivative as a dopant.

12. The organic electroluminescent device as described in claim 8, wherein the emission layer comprises the borane derivative as a dopant.

13. The organic electroluminescent device as described in claim 7, wherein the emission layer comprises the coumarin derivative as a dopant.

14. The organic electroluminescent device as described in claim 8, wherein the emission layer comprises the coumarin derivative as a dopant.

15. The organic electroluminescent device as described in claim 7, wherein the emission layer comprises the pyran derivative as a dopant.

16. The organic electroluminescent device as described in claim 8, wherein the emission layer comprises the pyran derivative as a dopant.

17. The organic electroluminescent device as described in claim 7, wherein the emission layer comprises the iridium complex as a dopant.

18. The organic electroluminescent device as described in claim 8, wherein the emission layer comprises the iridium complex as a dopant.

19. The organic electroluminescent device as described in claim 7, wherein the emission layer comprises the platinum complex as a dopant.

20. The organic electroluminescent device as described in claim 8, wherein the emission layer comprises the platinum complex as a dopant.
